(19) United States
(12) Patent Application Publication
(10) Pub. No.: US 2025/0220997 A1
(43) Pub. Date: Jul. 3, 2025

(54) SEMICONDUCTOR DEVICE, ELECTRONIC APPARATUS HAVING THE SAME, AND METHOD OF MANUFACTURING THE SAME

(71) Applicant: Samsung Electronics Co., Ltd., Suwon-si (KR)

(72) Inventors: Kyooho JUNG, Suwon-si (KR); Jeeeun YANG, Suwon-si (KR); Sangwook KIM, Suwon-si (KR); Jungkyun KIM, Suwon-si (KR); Narae HAN, Suwon-si (KR)

(73) Assignee: Samsung Electronics Co., Ltd., Suwon-si (KR)

(21) Appl. No.: 19/006,756

(22) Filed: Dec. 31, 2024

(30) Foreign Application Priority Data
Jan. 3, 2024 (KR) 10-2024-0001064
Dec. 4, 2024 (KR) 10-2024-0178922

(51) Int. Cl. H10D 62/17; H10D 30/01; H10D 30/63; H10D 62/40; H10D 62/86; H10D 64/27

(52) U.S. Cl. CPC H10D 62/235; H10D 30/025; H10D 30/63; H10D 62/402; H10D 62/86; H10D 64/512

(57) ABSTRACT

Provided is a semiconductor device. The semiconductor device includes a first electrode, a second electrode spaced apart from the first electrode, a channel between the first electrode and the second electrode, a gate insulating layer in the channel, and a gate electrode on the gate insulating layer. The channel includes a plurality of oxide semiconductor layers spaced apart from each other and a crystallization reduction layer between the plurality of oxide semiconductor layers.

### CROSS-REFERENCE TO RELATED APPLICATION

This application is based on and claims priority under 35 U.S.C. § 119 to Korean Patent Application Nos. 10-2024-0001064, filed on Jan. 3, 2024, and 10-2024-0178922, filed on Dec. 4, 2024 in the Korean Intellectual Property Office, the disclosures of each of which are incorporated by reference herein in their entirety.

### BACKGROUND

Some example embodiments relate to a semiconductor device including a crystallization prevention layer or crystallization reduction layer that suppresses or reduces crystallization of an oxide semiconductor layer, an electronic apparatus having the semiconductor device, and/or a method of manufacturing the semiconductor device.

Transistors are or include semiconductor devices that serve as electrical switches and are used in various integrated circuit (IC) devices including memories, driving ICs, logic devices, etc. In order to increase the degree of integration of IC devices, the space occupied by a transistor therein is rapidly reduced, and research has been conducted to maintain the performance of the IC devices while reducing the size of the transistor.

Silicon is often used as a channel of transistors. Silicon-based transistors have a high off-current, and the smaller the size (e.g., the channel length) of the transistor, the worse the off-current problem may be. On the other hand, oxide semiconductors have a side bandgap compared to silicon and thus have a lower off-current than silicon channels, and accordingly, they are suitable for miniaturized transistors.

### SUMMARY

Provided are a semiconductor device including a crystallization prevention layer or crystallization reduction layer that suppresses or reduces crystallization of an oxide semiconductor layer, and/or a method of manufacturing the semiconductor device.

Additional aspects will be set forth in part in the description which follows and, in part, will be apparent from the description, or may be learned by practice of the presented embodiments of the disclosure.

According to some example embodiments, a semiconductor device includes a first electrode, a second electrode spaced apart from the first electrode, a channel between the first electrode and the second electrode, a gate insulating layer in the channel, and a gate electrode on the gate insulating layer. The channel includes a plurality of oxide semiconductor layers spaced apart from each other, and a crystallization reduction layer between the plurality of oxide semiconductor layers. A total thickness of the channel is in a range of 5 nm to 10 nm, the channel is in an amorphous state, and the crystallization reduction layer has a thickness in a range of 1 Å to 10 Å.

Alternatively or additionally according to some example embodiments, an electronic apparatus includes a memory comprising at least one semiconductor device, and a memory controller, wherein the at least one semiconductor device includes a first electrode, a second electrode spaced apart from the first electrode, a channel provided between the first electrode and the second electrode, a gate insulating layer in the channel, and a gate electrode on the gate insulating layer, the channel includes a plurality of oxide semiconductor layers spaced apart from each other, and a crystallization reduction layer between the plurality of oxide semiconductor layers. A total thickness of the channel is in a range of 5 nm to 10 nm, the channel is in an amorphous state, and the crystallization reduction layer has a thickness in a range of 1 Å to 10 Å.

Alternatively or additionally according to some example embodiments, a method of manufacturing a semiconductor device includes forming a first electrode, forming a channel comprising an oxide semiconductor on the first electrode, forming a gate insulating layer on the channel, forming a gate electrode on the gate insulating layer, and forming a second electrode so as to be electrically connected to the channel. The forming of the channel includes forming a first oxide semiconductor layer, forming a crystallization reduction layer on the first oxide semiconductor layer, and forming a second oxide semiconductor layer on the crystallization reduction layer, and the crystallization reduction layer includes a material having an energy bandgap greater than an energy band gap of each of the first oxide semiconductor layer and the second oxide semiconductor layer.

### BRIEF DESCRIPTION OF THE DRAWINGS

The above and other aspects, features, and advantages of certain example embodiments will be more apparent from the following description taken in conjunction with the accompanying drawings, in which:

FIG. 1 schematically illustrates a semiconductor device according to some example embodiments;

FIG. 2 illustrates an example of a semiconductor device including two crystallization prevention layers according to some example embodiments;

FIG. 3 illustrates an example of a semiconductor device including three crystallization prevention layers according to some example embodiments;

FIG. 4A shows a transmission electron microscope (TEM) image obtained by heating a semiconductor device of a comparative example at 400° C.;

FIG. 4B shows a TEM image obtained by heating the semiconductor device of the comparative example at 450° C.;

FIG. 4C shows a TEM image obtained by heating the semiconductor device of the comparative example at 500° C.;

FIG. 4D shows a TEM image obtained by heating the semiconductor device of the comparative example at 600° C.;

FIG. 5 illustrates carrier mobility according to temperature with respect to the semiconductor device of a comparative example;

FIG. 6 illustrates a change in a current according to a gate voltage for each heat treatment temperature with respect to the semiconductor device of a comparative example;

FIG. 7A shows a TEM photograph of a semiconductor device according to some example embodiments;

FIG. 7B illustrates an energy dispersive X-ray (EDX) analysis result of a semiconductor device according to some example embodiments;

FIG. 7C illustrates an EDX line scan result of a semiconductor device according to some example embodiments;

FIG. 8A illustrates results of X-ray diffraction (XRD) analysis after heat treatment at 700° C. on an oxide semiconductor layer that does not include aluminum;

FIG. 8B illustrates results of XRD analysis after heat treatment at 700° C. on an oxide semiconductor layer including an aluminum oxide layer (crystallization prevention layer) according to some example embodiments; FIG. 8C illustrates results of XRD analysis after heat treatment at 700° C. on an oxide semiconductor layer in that aluminum is doped;

FIG. 9 is a cross-sectional view of a semiconductor device according to some example embodiments;

FIG. 10 is a cross-sectional view of a semiconductor device according to some example embodiments;

FIG. 11 is a cross-sectional view of a semiconductor device according to some example embodiments;

FIG. 12 is a cross-sectional view of a semiconductor device according to some example embodiments;

FIG. 13 is a cross-sectional view of a semiconductor device according to some example embodiments;

FIG. 14 is a cross-sectional view of a semiconductor device according to some example embodiments;

FIGS. 15A and 15B are flowcharts illustrating a method of manufacturing a semiconductor device according to some example embodiments;

FIG. 16 is a diagram illustrating an ALD method used in a method of manufacturing a semiconductor device according to some example embodiments;

FIGS. 17 to 28 are diagrams illustrating a method of manufacturing a semiconductor device according to some example embodiments;

FIG. 29 illustrates a memory device including a semiconductor device according to some example embodiments;

FIG. 30 is a schematic block diagram of a display driver integrated circuit (IC) (DDI) including a semiconductor device and a display device including the DDI according to some example embodiments;

FIG. 31 is a circuit diagram of a CMOS inverter including a semiconductor device according to some example embodiments;

FIG. 32 is a circuit diagram of a CMOS SRAM device including a semiconductor device according to some example embodiments;

FIG. 33 is a circuit diagram of a CMOS NAND circuit including a semiconductor device according to some example embodiments;

FIG. 34 is a block diagram of an electronic system including a semiconductor device according to some example embodiments; and

FIG. 35 is a block diagram of an electronic apparatus including a semiconductor device according to some example embodiments.

### DETAILED DESCRIPTION

Reference will now be made in detail to some embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereinafter, a semiconductor device and/or a method of manufacturing the same according to various example embodiments are described in detail with reference to the accompanying drawings. In the drawings, like reference numerals in the drawings denote like elements, and sizes of components in the drawings may be exaggerated for clarity and convenience of explanation. While such terms as “first,” “second,” etc., may be used to describe various components, such components must not be limited to the above terms. The above terms are used only to distinguish one component from another.

An expression used in the singular encompasses the expression of the plural, unless it has a clearly different meaning in the context. When a portion “includes” an element, another element may be further included, rather than excluding the existence of the other element, unless otherwise described. Sizes or thicknesses of components in the drawings may be arbitrarily exaggerated for convenience of explanation. Further, when a certain material layer is described as being disposed on a substrate or another layer, the material layer may be in contact with the other layer, or there may be a third layer between the material layer and the other layer. In the following embodiments, materials constituting each layer are provided merely as an example, and other materials may also be used.

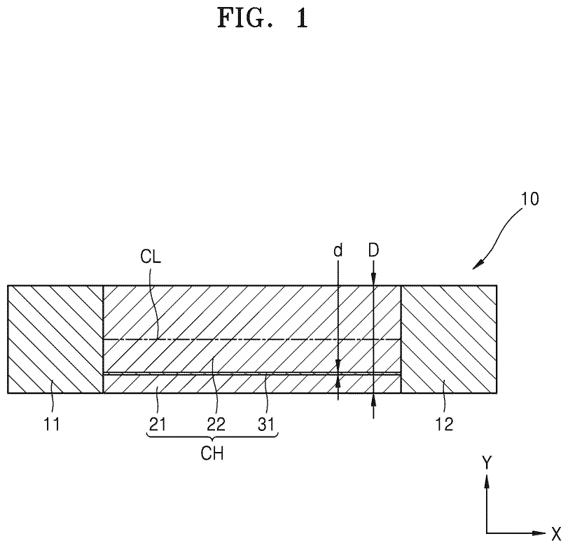

FIG. 1 schematically illustrates a semiconductor device 10 according to some example embodiments.

The semiconductor device 10 may include a first electrode 11, a second electrode 12 spaced apart from the first electrode 11, and a channel CH between the first electrode 11 and the second electrode 12. The channel CH may include a plurality of oxide semiconductor layers 21 and 22 spaced apart from each other and a first crystallization prevention layer or first crystallization reduction layer 31 inserted between the plurality of oxide semiconductor layers 21 and 22.

When the semiconductor device 10 is applicable to a planar transistor, the first electrode 11 may correspond to one of a source electrode or a drain electrode, and the second electrode 12 may correspond to another of the source electrode and the drain electrode. Alternatively, when the semiconductor device 10 is applied to a vertical channel transistor, the first electrode 11 and the second electrode 12 may be arranged in a Y direction and the channel CH may be arranged long in a Y direction in the drawing. The first electrode 11 may correspond to a lower drain electrode or lower source electrode, and the second electrode 12 may correspond to an upper source electrode or upper drain electrode. The first electrode 11 and the second electrode 12 may include, for example, magnesium (Mg), aluminum (Al), scandium (Sc), titanium (Ti), vanadium (V), chromium (Cr), manganese (Mn), nickel (Ni), copper (Cu), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), and any combination thereof. Alternatively or additionally, the first electrode 11 and the second electrode 12 may be nitrides including the above materials. However, the materials of the first electrode 11 and the second electrode 12 are not limited thereto.

In FIG. 1, the first electrode 11 and the second electrode 12 are provided on both sides of the channel CH, respectively, but the first electrode 11 and the second electrode 12 may be spaced apart from each other on an upper surface of the channel CH.

The plurality of oxide semiconductor layers 21 and 22 may include a first oxide semiconductor layer 21 and a second oxide semiconductor layer 22. The first crystallization prevention layer 31 may be between the first oxide semiconductor layer 21 and the second oxide semiconductor layer 22. The first crystallization prevention layer 31 may be disposed to be in direct contact with the first oxide semiconductor layer 21 and the second oxide semiconductor layer 22. A lower surface and an upper surface of the first crystallization prevention layer 31 may be in direct contact with the first oxide semiconductor layer 21 and the second oxide semiconductor layer 22, respectively. For example, the first crystallization prevention layer 31 may have a layer structure inside the channel CH. The thicknesses of the first oxide semiconductor layer 21 and the second oxide semiconductor layer 22 may be different from each other

The first crystallization prevention layer 31 may extend from the first electrode 11 to the second electrode 12 in an X direction. An extension direction of the first crystallization prevention layer 31 is not limited thereto, and may be determined according to a deposition direction in a process in which the channel CH is deposited.

The first oxide semiconductor layer 21 and the second oxide semiconductor layer 22 may be oxides including at least one of indium (In), gallium (Ga), or zinc (Zn). For example, the first oxide semiconductor layer 21 and the second oxide semiconductor layer 22 may include at least one of InGaZnO, In₂O₃, InZnO, or InGaO. The first oxide semiconductor layer 21 and the second oxide semiconductor layer 22 may include at least some of the same material and/or at least some different materials.

The first crystallization prevention layer 31 may include a material having an energy band gap greater than an energy band gap of each of the first oxide semiconductor layer 21 and the second oxide semiconductor layer 22. The first crystallization prevention layer 31 may include at least one of aluminum oxide, gallium oxide, silicon oxide, zirconium oxide, hafnium oxide, silicon nitride, aluminum nitride, and gallium nitride. Alternatively or additionally, the first crystallization prevention layer 31 may not include any of the same element apart from oxygen as, or, any of same material as the first oxide semiconductor layer 21 and the second oxide semiconductor layer 22. For example, the first crystallization prevention layer 31 may include at least one of Al₂O₃, GaOx, SiO₂, ZrO₂, HfO₂, SiN, AlN, or GaN. The first crystallization prevention layer 31 may be between the first oxide semiconductor layer 21 and the second oxide semiconductor layer 22 to suppress crystallization of the first oxide semiconductor layer 21 and the second oxide semiconductor layer 22. Accordingly, the channel CH may have an amorphous state even at a relatively high temperature. The first crystallization prevention layer 31 may be disposed at various positions within the channel CH. For example, the first crystallization prevention layer 31 may be biased to one side with respect to a ½ line of a total thickness D of the channel CH, that is, a center line CL. For example, the first crystallization prevention layer 31 may be disposed below the center line CL. However, example embodiments are not limited thereto, and the first crystallization prevention layer 31 may be disposed on the center line CL.

In FIG. 1, the first crystallization prevention layer 31 is disposed between the first electrode 11 and the second electrode 12, but a plane of the first crystallization prevention layer 31 may be disposed to face the first electrode 11 or the second electrode 12 according to a structure of a semiconductor device. In this case, the first crystallization prevention layer 31 may be located relatively closer to the first electrode 11 or the second electrode 12 facing the first crystallization prevention layer 31. This may be because the channel CH facing an electrode closely is better crystalized, so that crystallization of the channel CH may be more effectively suppressed by arranging the first crystallization prevention layer 31 close to the electrode. In FIG. 1, the first crystallization prevention layer 31 does not face the first electrode 11 or the second electrode 12, and thus, the first crystallization prevention layer 31 may be located on the center line CL.

The semiconductor device 10 may be used in an ultra-small integrated circuit (IC), although example embodiments are not limited thereto. Therefore, the thickness of each layer of the semiconductor device 10 may be very thin. For example, the total thickness D of the channel CH may be in a range of about 5 nm to about 10 nm. In some example embodiments, the first crystallization prevention layer 31 may have a thickness in a range of about 1 Å to about 10 Å. For example, the first crystallization prevention layer 31 may have the thickness in a range of about 3 Å to about 5 Å. Even though the thickness D of the channel CH is small, the channel CH is not crystallized at a high temperature and maintains or at least is more likely to maintain an amorphous state, and thus an off-current may be reduced.

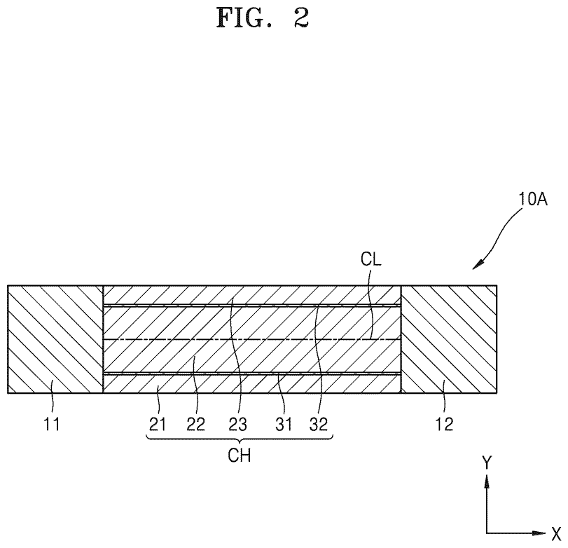

FIG. 2 illustrates a semiconductor device 10A including a first crystallization prevention layer 31 and a second crystallization reduction layer or second crystallization prevention layer 32. The semiconductor device 10A may include a first oxide semiconductor layer 21, a second oxide semiconductor layer 22, and a third oxide semiconductor layer 23. The first crystallization prevention layer 31 may be disposed between the first oxide semiconductor layer 21 and the second oxide semiconductor layer 22, and the second crystallization prevention layer 32 may be disposed between the second oxide semiconductor layer 22 and the third oxide semiconductor layer 23.

In FIG. 2, the first oxide semiconductor layer 21, the first crystallization prevention layer 31, the second oxide semiconductor layer 22, the second crystallization prevention layer 32, and the third oxide semiconductor layer 23 may configure the channel CH. The first crystallization prevention layer 31 and the second crystallization prevention layer 32 may be disposed symmetrically with respect to a thickness direction (Y direction) of the channel CH. Herein, the thickness may mean a relatively small width. However, the arrangement structure of the first crystallization prevention layer 31 and the second crystallization prevention layer 32 is not limited thereto, and both the first crystallization prevention layer 31 and the second crystallization prevention layer 32 may be disposed between a lower surface of the channel CH and the center line CL of the channel CH. Alternatively, both the first crystallization prevention layer 31 and the second crystallization prevention layer 32 may be disposed between an upper surface of the channel CH and the center line CL of the channel CH. Alternatively, the first crystallization prevention layer 31 may be disposed on the center line CL of the channel CH, and the second crystallization prevention layer 32 may be disposed between the lower surface of the channel CH and the center line CL of the channel CH.

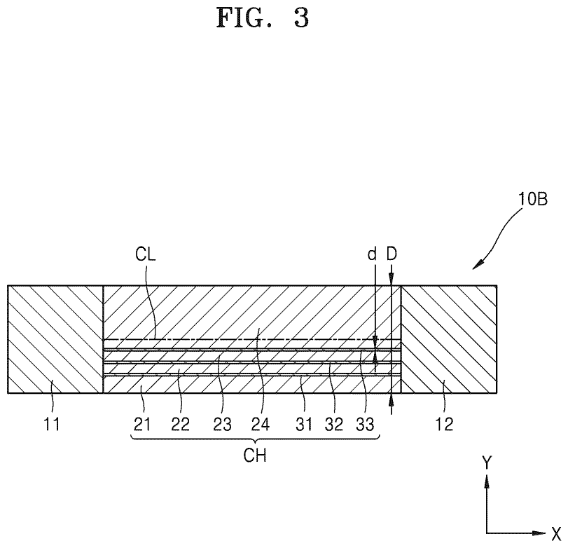

FIG. 3 illustrates a semiconductor device 10B having the first crystallization prevention layer 31, the second crystallization prevention layer 32, and a third crystallization prevention layer 33. The semiconductor device 10B may include the first oxide semiconductor layer 21, the second oxide semiconductor layer 22, the third oxide semiconductor layer 23, and a fourth oxide semiconductor layer 24. The first crystallization prevention layer 31 may be disposed between the first oxide semiconductor layer 21 and the second oxide semiconductor layer 22, the second crystallization prevention layer 32 may be disposed between the second oxide semiconductor layer 22 and the third oxide semiconductor layer 23, and the third crystallization prevention layer 33 may be disposed between the third oxide semiconductor layer 23 and the fourth oxide semiconductor layer 24. In FIG. 3, the first oxide semiconductor layer 21, the first crystallization prevention layer 31, the second oxide semiconductor layer 22, the second crystallization prevention layer 32, the third oxide semiconductor layer 23, the third crystallization prevention layer 33, and the fourth oxide semiconductor layer 24 may configure the channel CH.

The first crystallization prevention layer 31, the second crystallization prevention layer 32, and the third crystallization prevention layer 33 may be disposed, for example, between a lower surface of the channel CH and a position of ½ of the thickness D of the channel CH, that is, the center line CL. However, the positions of the first crystallization prevention layer 31, the second crystallization prevention layer 32, and the third crystallization prevention layer 33 are not limited thereto. For example, the first crystallization prevention layer 31, the second crystallization prevention layer 32, and the third crystallization prevention layer 33 may be disposed between the center lines CL of the channel CH on an upper surface of the channel CH. Alternatively, the first crystallization prevention layer 31 may be disposed between the lower surface of the channel CH and the center line CL of the channel CH, and the second crystallization prevention layer 32 and the third crystallization prevention layer 33 may be disposed between the upper surface of the channel CH and the center line CL of the channel CH. Alternatively, the first crystallization prevention layer 31 may be disposed on the center line CL of the channel CH, and the second crystallization prevention layer 32 and the third crystallization prevention layer 33 may be disposed between the upper surface of the channel CH and the center line CL of the channel CH. In addition, the positions of the first crystallization prevention layer 31, the second crystallization prevention layer 32, and the third crystallization prevention layer 33 may be variously set.

A material composition of the first crystallization prevention layer 31 may be the same as, or different from, a material composition of the second crystallization prevention layer 32. For example, the first crystallization prevention layer 31 may include a material that is or is not included in the second crystallization prevention layer 32; alternatively or additionally, the second crystallization prevention layer 32 may include a material that is or is not included in the first crystallization prevention layer 31. Example embodiments are not limited thereto.

Meanwhile, three or more crystallization prevention layers may be provided, each having the same or different material compositions, and/or the same or different thicknesses. The total thickness D of the channel CH may be in a range of about 5 nm to about 10 nm. In addition, the first crystallization prevention layer 31, the second crystallization prevention layer 32, and the third crystallization prevention layer 33 may each have a thickness d in a range of about 1 Å to about 10 Å, and may or may not have the same thickness. Alternatively, the thickness d may be in a range of about 3 Å to about 5 Å. A ratio of the sum of the thickness d of the first crystallization prevention layer 31, the second crystallization prevention layer 32, and the third crystallization prevention layer 33 to the total thickness D of the channel CH may in a range of about 0.01 to about 0.6. When the ratio of the sum of the thickness d of the first crystallization prevention layer 31, the second crystallization prevention layer 32, and the third crystallization prevention layer 33 to the total thickness D of the channel CH is out of the range, carrier mobility may degrade.

Next, a function of a crystallization prevention layer of a semiconductor device according to some example embodiments is described. Here, crystallization of a comparative example including a W electrode, an IGZO oxide semiconductor layer, and a TiN electrode is described.

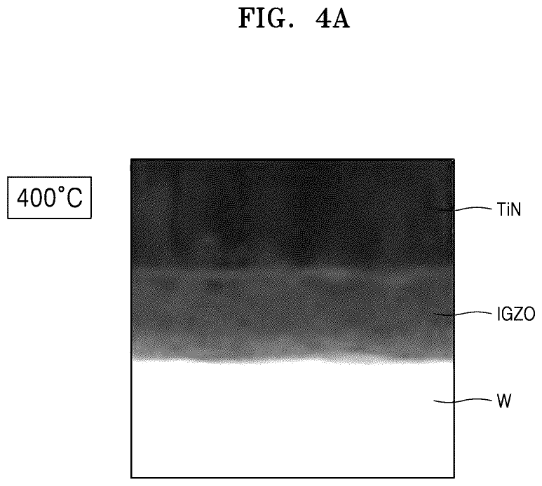

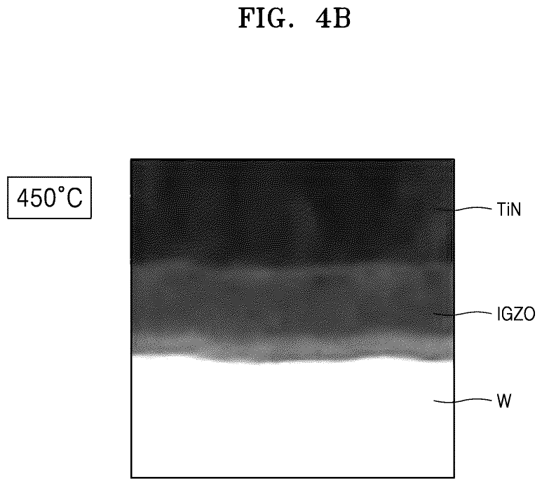

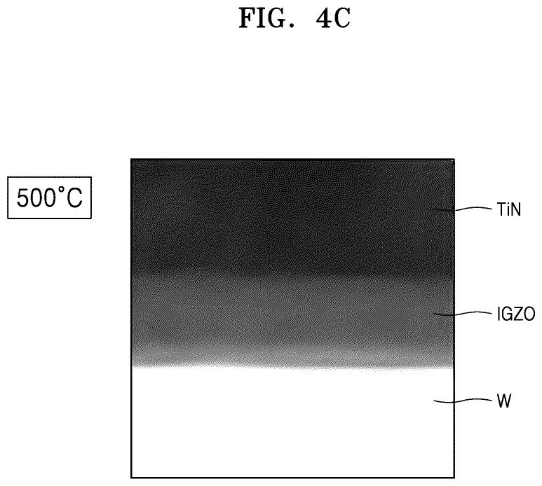

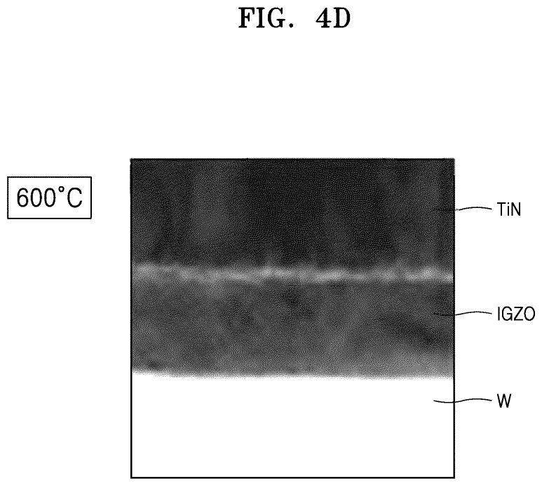

FIG. 4A shows a transmission electron microscope (TEM) image obtained by heating a structure of a comparative example at 400° C., FIG. 4B shows a TEM image obtained by heating the structure of the comparative example at 450° C., FIG. 4C shows a TEM image obtained by heating the structure of the comparative example at 500° C., and FIG. 4D shows a TEM image obtained by heating the structure of the comparative example at 600° C. The structure of the comparative example starts to be crystallized from 450° C., and the IGZO oxide semiconductor layer is entirely crystallized at 600° C. In a subsequent process after the deposition of the IGZO oxide semiconductor layer, a plurality of operations, such as annealing operations and/or deposition operations, are performed at 400° C. or more and a plurality of operations, such as annealing operations and/or deposition operations, are performed at 300° C. or more. Due to the subsequent process at such high temperatures, the IGZO oxide semiconductor layer is crystallized.

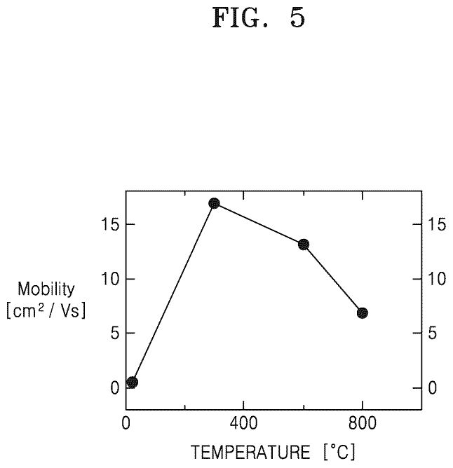

FIG. 5 illustrates carrier mobility according to the temperature of the comparative example. In FIG. 5, the carrier mobility decreases at a high temperature at which an oxide semiconductor layer is crystallized. Referring to FIG. 5, in the comparative example, a gate induced drain leakage (GIDL) degrades due to crystallization of the oxide semiconductor layer, and a source/drain contact is oxidized, etc., which may cause a problem of thermal stability.

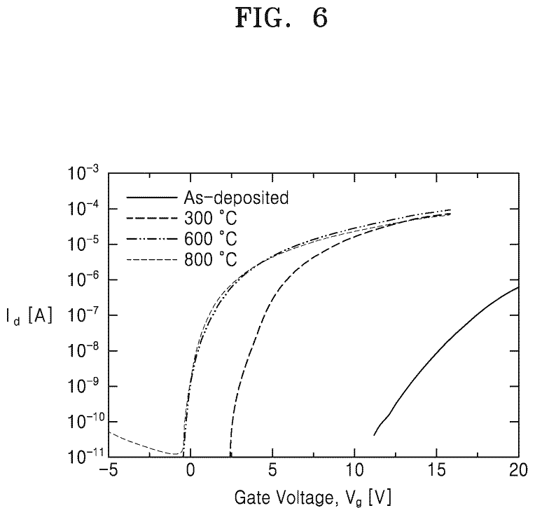

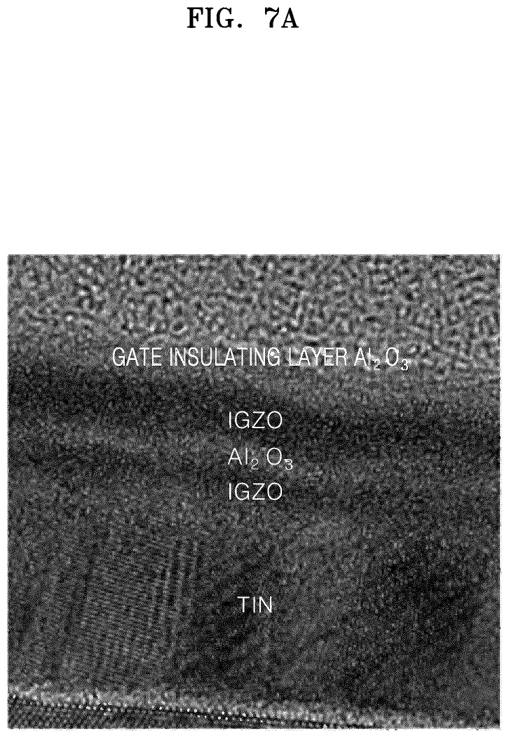

FIG. 6 illustrates a graph of a drain current according to a gate voltage of a semiconductor device in a comparative example. Referring to FIG. 6, an off-current appears at high temperatures of 600° C. and 800° C. This may be because an oxide semiconductor device is crystallized at high temperatures of 600° C. and 800° C.

Therefore, in a semiconductor device according to some example embodiments, the channel CH includes a crystallization prevention layer so that crystallization is suppressed even at high temperatures. In some example embodiments, the channel CH may become amorphous even at high temperatures, and have a low off-current. Referring to FIGS. 1, 2, and 3, the channel CH includes the first to third crystallization prevention layers 31, 32, and 33 between the first to fourth oxide semiconductor layers 21, 22, 23, and 24 to have an amorphous state, and have a low off-current.

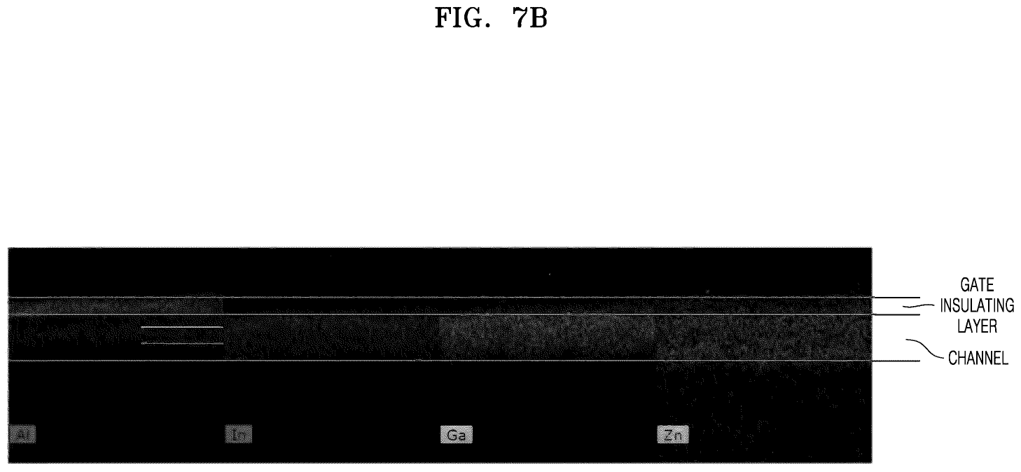

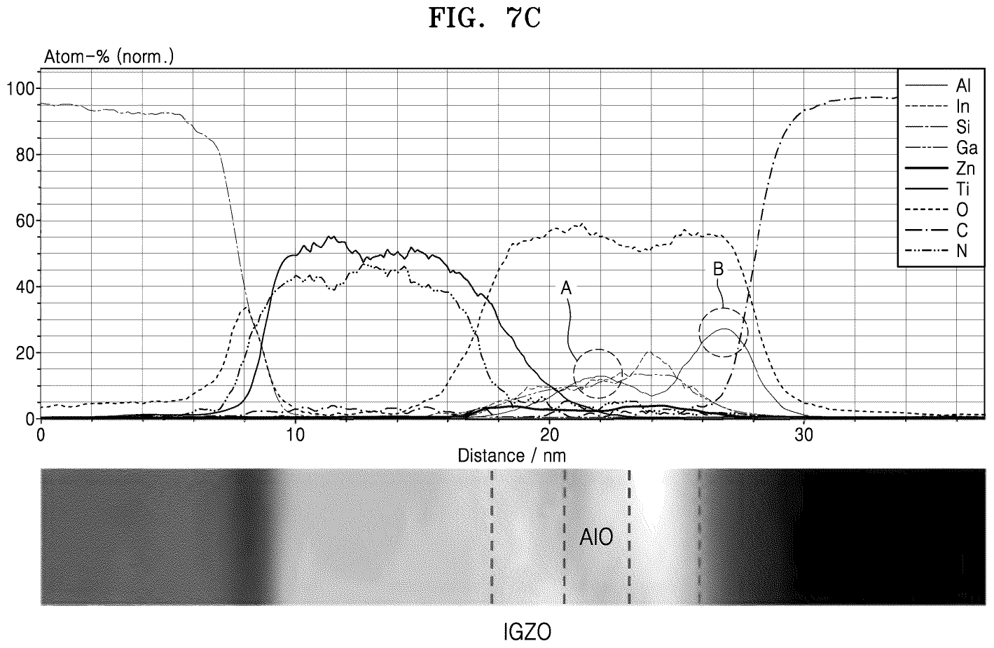

FIG. 7A shows a TEM photograph of a semiconductor device according to some example embodiments. Referring to FIG. 7A, the semiconductor device according to some example embodiments has a stack structure including a TiN electrode/IGZO channel/Al₂O₃ crystallization prevention layer/IGZO channel/Al₂O₃ gate insulating layer, the IGZO channel has an amorphous structure, and the Al₂O₃ crystallization prevention layer has a layer structure.

FIG. 7B illustrates an energy dispersive X-ray (EDX) analysis result of a semiconductor device according to some example embodiments. FIG. 7C illustrates an EDX line scan result of the semiconductor device. According to the results, it may be confirmed that aluminum oxide exists in a separate layer structure between IGZO materials. In FIG. 7C, part A represents the crystallization prevention layer including aluminum oxide, and part B represents the gate insulating layer including aluminum oxide.

On the other hand, the first to third crystallization prevention layers 31, 32, and 33 are not provided between the first to fourth oxide semiconductor layers 21, 22, 23, and 24, but are provided on a lower interface of the channel CH or an upper interface of the channel CH, which may reduce the crystallization suppression effect or may not contribute to crystallization suppression. In addition, even when the first to third crystallization prevention layers 31, 32, and 33 are doped with dopants rather than a layer structure, the crystallization suppression effect may be reduced.

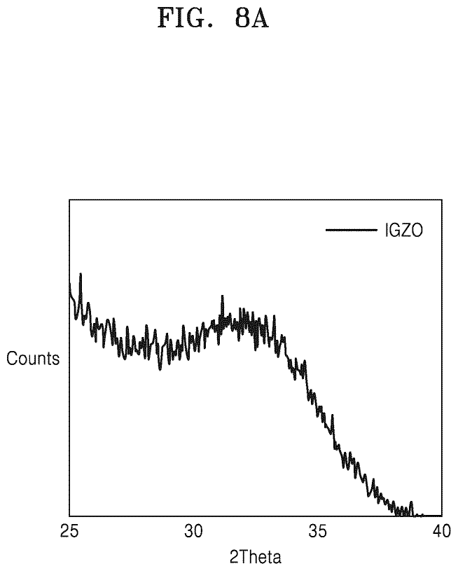

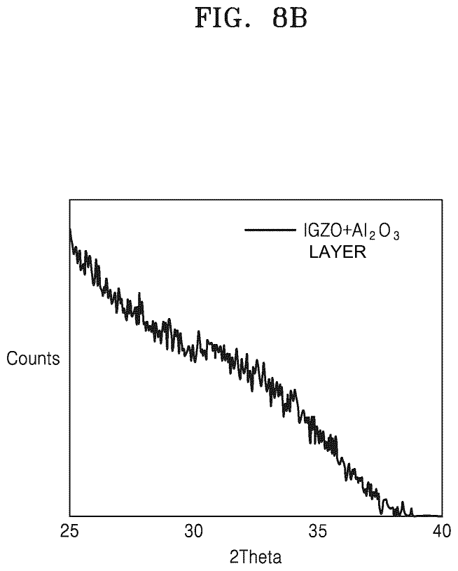

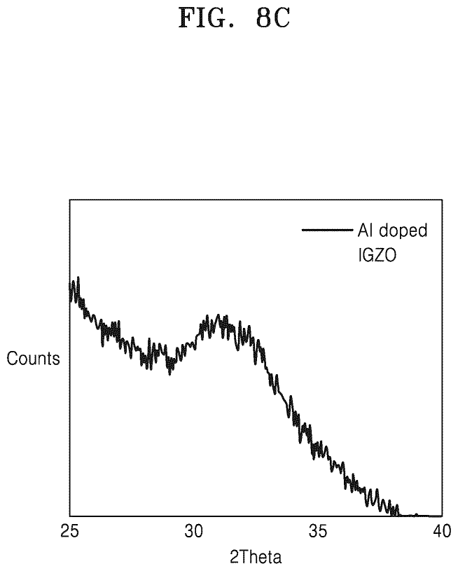

FIG. 8A illustrates crystallinity of a crystallized IGZO channel without aluminum, FIG. 8B illustrates crystallinity of the channel of a semiconductor device according to some example embodiments, and FIG. 8C illustrates crystallinity of the channel of a comparative example. In FIGS. 8A, 8B, and 8C, the channel includes an oxide semiconductor of In:Ga:Zn=3:2:1. These graphs show a light intensity according to 2 theta that is a crystallization specific angle. A crystal structure of the material may be known according to a peak value at a specific angle. The crystal structure of the material may be analyzed based on a diffraction that occurs when an X-ray is irradiated to the crystal structure at a specific angle of 2 theta. Referring to FIG. 8A, a peak value of the crystallized IGZO channel appears in a range of about 29° to about 34°. FIG. 8B illustrates the crystallinity of the channel when aluminum oxide has a separate layer structure in an IGZO/aluminum oxide/IGZO structure. Here, the total thickness of the channel (IGZO/aluminum oxide/IGZO structure) is 7 nm, a thickness of the crystallization prevention layer including aluminum oxide is 5 Å, and the crystallization prevention layer including aluminum oxide is provided at ⅓ of the total thickness of the channel from a lower interface of the channel. FIG. 8C illustrates crystallinity of the channel of the comparative example. In the comparative example, the channel includes the IGZO channel layer having a thickness of 7 nm without a separate crystallization prevention layer and is doped with Al. In the comparative example, when the IGZO channel layer is deposited, In, Ga, Zn, and Al layers may be deposited in a super cycle. For example, the IGZO channel layer of the comparative example may be deposited by repeating In 9cy+Ga 6cy+Zn 3cy+Al 1cy 30 times through an ALD method. The channels of FIGS. 8B and 8C have the same element content (at %) of Al among all elements excluding oxygen. For example, the channels of FIGS. 8B and 8C include 12.5 at % of aluminum.

As a result of heating structures of some example embodiments and the comparative example at 700° C. and performing an X-ray diffraction (XRD) analysis, in the example embodiments (FIG. 8B), no peak value appears at a specific crystallization angle with respect to IGZO, for example, in a range of about 29° to about 34°. On the other hand, in the comparative example (FIG. 8C), a peak value appears in the specific crystallization angle in the range of about 29° to about 34°. This may indicate that the structure of the comparative example is crystallized. As described above, when the semiconductor device according to the embodiment includes a crystallization prevention layer inside the channel, the channel maintains an amorphous state at a relatively high temperature of about 700° C. However, in the comparative example in which Al oxide is not provided as a separate layer and Al is doped in the channel, it may be confirmed that the channel is crystallized. The IGZO channel doped with Al indicates that there is little crystallization suppression effect of the IGZO channel when the IGZO channel is doped with Al.

When an oxide semiconductor layer is in an amorphous state, a leakage current may be reduced. Alternatively or additionally, the semiconductor device according to some example embodiments may have a thermal stability without being crystallized even at a high temperature of about 700° C. Accordingly, the crystallization temperature of the semiconductor device according to some example embodiments may be 700° C. or more.

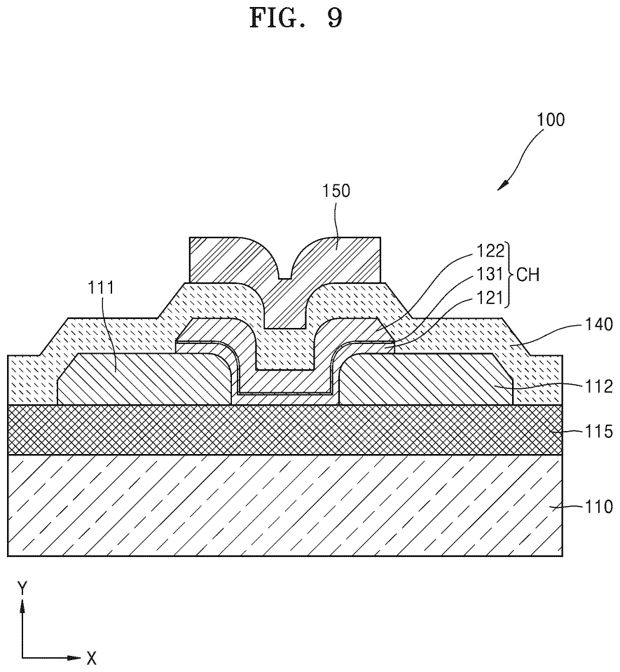

FIG. 9 illustrates an example in which a semiconductor device 100 according to some example embodiments is applied to a planar transistor.

The semiconductor device 100 includes a substrate 110, a first electrode 111 provided on the substrate 110, a second electrode 112 spaced apart from the first electrode 111, the channel CH provided between the first electrode 111 and the second electrode 112, a gate insulating layer 140 provided on the channel CH, and a gate electrode 150 provided on the gate insulating layer 140. A buffer layer 115 may be further provided between the substrate 110 and the channel CH. The buffer layer 115 may include, for example, SiO₂. However, the buffer layer 115 is not limited thereto.

The substrate 110 may include, for example, one or more of Si, Ge, SiGe, or a group III-V semiconductor material. The substrate 110 may be or may include, for example, a silicon substrate having a silicon oxide formed on a surface thereof, but is not limited thereto.

The first electrode 111 may be or correspond to a source electrode, and the second electrode 112 may be or correspond to a drain electrode. The channel CH may include a plurality of oxide semiconductor layers 121 and 122 and a crystallization prevention layer 131 provided between the plurality of oxide semiconductor layers 121 and 122. The channel CH may extend between the first electrode 111 and the second electrode 112 and to some upper regions of the first electrode 111 and the second electrode 112. The crystallization prevention layer 131 may be disposed relatively close to the first electrode 111 and the second electrode 112. For example, the crystallization prevention layer 131 may be disposed close to the first electrode 111 which is the source electrode and the second electrode 112 which is the drain electrode in the thickness direction (Y direction) of the channel CH. A distance from a lower interface of the channel CH to the crystallization prevention layer 131 may be less than a distance from an upper interface of the channel CH to the crystallization prevention layer 131. Although FIG. 9 shows one crystallization prevention layer 131, when a plurality of crystallization prevention layers 131 are provided, all of the crystallization prevention layers 131 may be disposed closer to the lower interface of the channel CH than to the upper interface of the channel CH. When the crystallization prevention layer 131 is disposed close to the first electrode 111 and the second electrode 112, the crystallization prevention effect may be enhanced.

FIG. 9 illustrates an example in which the plurality of oxide semiconductor layers 121 and 122 include a first oxide semiconductor layer 121 and a second oxide semiconductor layer 122, and the crystallization prevention layer 131 is provided between the first oxide semiconductor layer 121 and the second oxide semiconductor layer 122. In some cases, examples as shown in FIGS. 2 and/or 3 may be applied as the channel CH. The configuration and characteristics of the channel CH are substantially the same as those described with reference to FIGS. 1 to 3, and thus detailed descriptions thereof are omitted.

The first electrode 111 and the second electrode 112 may each include a metal material. The first electrode 111 and the second electrode 112 may each include at least one selected from the group consisting of or including W (tungsten), Co (cobalt), Ni (nickel), Fe (iron), Ti (titanium), Mo (molybdenum), Cr (chromium), Zr (zirconium), Hf (hafnium), Nb (niobium), Ta (tantalum), Ag (silver), Au (gold), Al (aluminum), Cu (copper), Sb (tin), V (vanadium), Ru (ruthenium), Pt (platinum), Zn (zinc), and Mg (magnesium), or a nitride including these materials. The first electrode 111 and the second electrode 112 may include the same materials; however, example embodiments are not limited thereto.

The gate insulating layer 140 may include, for example, Al₂O₃ and/or SiO₂. However, the gate insulating layer 140 is not limited thereto. The gate electrode 150 may include a metal material or a conductive oxide. Here, the metal material may include, for example, Au, Ti, TIN, TaN, W, Mo, WN, Pt, or Ni, any combination thereof. The conductive oxide may include, for example, Indium Tin Oxide (ITO), Indium Zinc Oxide (IZO), and Indium Zinc Oxide (IZO).

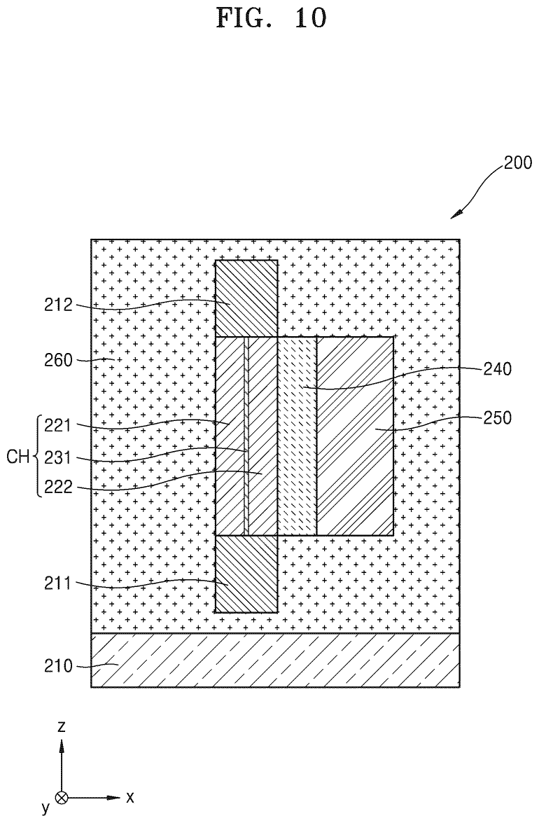

FIG. 10 illustrates a semiconductor device according to some example embodiments.

Referring to FIG. 10, the semiconductor device 200 includes a substrate 210, a first electrode 211 provided on the substrate 210, the channel CH provided in the first electrode 211, and a second electrode 212 provided in the channel CH. A gate insulating layer 240 may be provided at one side of the channel CH, and a gate electrode 250 may be provided on the gate insulating layer 240. The semiconductor device 200 may have a vertical channel structure.

The substrate 210 may be an insulating substrate or may be a semiconductor substrate having an insulating layer formed on a surface thereof. Alternatively, the substrate 210 may be a semiconductor substrate. The semiconductor substrate may include, for example, one or more of Si, Ge, SiGe, or a group III-V semiconductor material. The substrate 210 may be, for example, a silicon substrate having a silicon oxide formed on a surface thereof, but is not limited thereto.

The first electrode 211 and the second electrode 212 may each include a metal material. The first electrode 211 and the second electrode 212 may each include at least one selected from the group consisting of or including W (tungsten), Co (cobalt), Ni (nickel), Fe (iron), Ti (titanium), Mo (molybdenum), Cr (chromium), Zr (zirconium), Hf (hafnium), Nb (niobium), Ta (tantalum), Ag (silver), Au (gold), Al (aluminum), Cu (copper), Sb (tin), V (vanadium), Ru (ruthenium), Pt (platinum), Zn (zinc), and Mg (magnesium), or a nitride including these materials. For example, the first electrode 211 may include Zn having a content of 10 at % or less. Zn may have a content of 10 at % or less with respect to the total metal elements in the first electrode 211. Here, the content of Zn may represent the content of Zn with respect to the total metal elements included in the first electrode 211 excluding oxygen. For example, the first electrode 211 may include Zn having a content of 5 at % or less. The first electrode 211 may be spaced apart from the substrate 210.

The channel CH may be between the first electrode 211 and the second electrode 212, and may extend long in the direction (Z direction) perpendicular to the substrate 210. The first electrode 211 may be provided below the channel CH, and the second electrode 212 may be provided above the channel CH. The channel CH may include a plurality of oxide semiconductor layers 221 and 222 and a crystallization prevention layer 231 provided between the plurality of oxide semiconductor layers 211 and 222.

The plurality of oxide semiconductor layers 221 and 222 and the crystallization prevention layer 231 extend long in the direction (Z direction) perpendicular to the substrate 210. Here, a thickness direction of the channel CH indicates the X direction. Herein, the thickness indicates a thickness in a relatively small width direction. The channel CH described with reference to FIGS. 1, 2, and 3 may be applied.

The plurality of oxide semiconductor layers 221 and 222 may each be oxide including at least one of indium (In), gallium (Ga), or zinc (Zn). The plurality of oxide semiconductor layers 221 and 222 may include, for example, InGaZnO, In₂O₃, InZnO, or InGaO. The crystallization prevention layer 231 may include at least one of Al₂O₃, GaOx, SiO₂, ZrO₂, HfO₂, SiN, AlN, or GaN. The plurality of oxide semiconductor layers 221 and 222 may include the same material. However, example embodiments are not limited thereto, and the plurality of oxide semiconductor layers 221 and 222 may include the same and/or different materials. When a plurality of crystallization prevention layers 231 are provided, the plurality of crystallization prevention layers 231 may include the same material and/or different materials.

The crystallization prevention layer 231 may be disposed at a central position of the channel CH in the thickness direction (X direction) of the channel CH. However, the position of the crystallization prevention layer 231 is not limited thereto, and the crystallization prevention layer 231 may be disposed away from a central position of the channel CH in the thickness direction (X direction) of the channel CH. In addition, the positions of the crystallization prevention layers 231 may be variously set according to the number of the crystallization prevention layers 231.

The first electrode 211, the channel CH, and the second electrode 212 may be sequentially disposed without intervention of other layers in the direction (Z direction) perpendicular to the substrate 210. The first electrode 211, the channel CH, and the second electrode 212 may have the same width or different widths.

The gate electrode 250 may be disposed with its longitudinal direction (Z direction) perpendicular to the substrate 210. Herein, the longitudinal direction indicates a direction in which the length of the corresponding component is relatively long when viewed from the drawing. The channel CH, the gate insulating layer 240, and the gate electrode 250 may be arranged in a line in a horizontal direction (X direction) with respect to the substrate 210.

A mold insulating layer 260 may be provided on the substrate 210 to fill an empty space. The first electrode 211 may be spaced apart from the substrate 210 by the mold insulating layer 260.

As described above, the semiconductor device 200 according to some example embodiments includes the crystallization prevention layer 231 inside the channel CH to suppress crystallization of the oxide semiconductor layers 221 and 222, thereby reducing the leakage current and increasing the thermal stability.

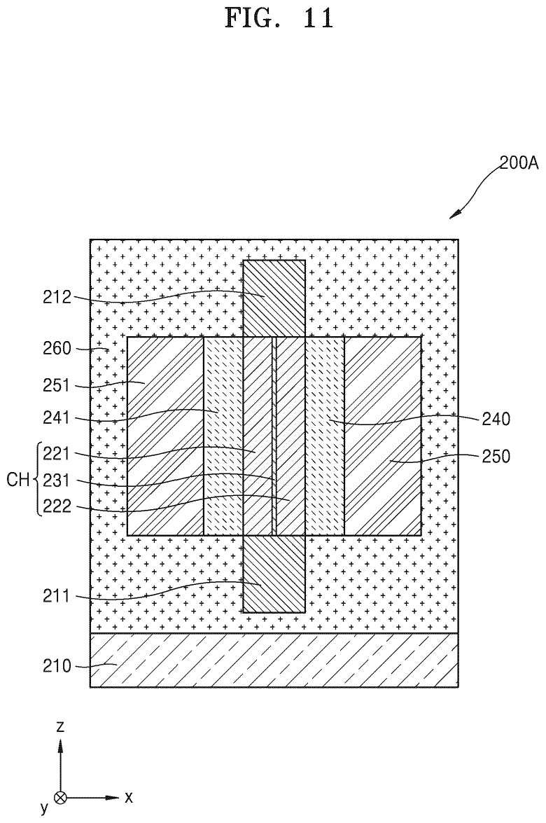

FIG. 11 illustrates a semiconductor device 200A of another example. In FIG. 11, components using the same reference numbers as in FIG. 10 have substantially the same configurations and effects as those described with reference to FIG. 10, and thus detailed descriptions thereof are omitted.

The semiconductor device 200A includes the first electrode 211, the channel CH, and the second electrode 212 arranged in the direction (Z direction) perpendicular to the substrate 210. The gate insulating layer 240 may be provided around the channel CH, and the gate electrode 250 may be provided around the gate insulating layer 240. The gate electrode 250 is provided around the channel CH to increase an area where the gate electrode 250 and the channel CH face each other, and improve a short channel effect. The semiconductor device 200A may be applied to a so-called gate all around structure.

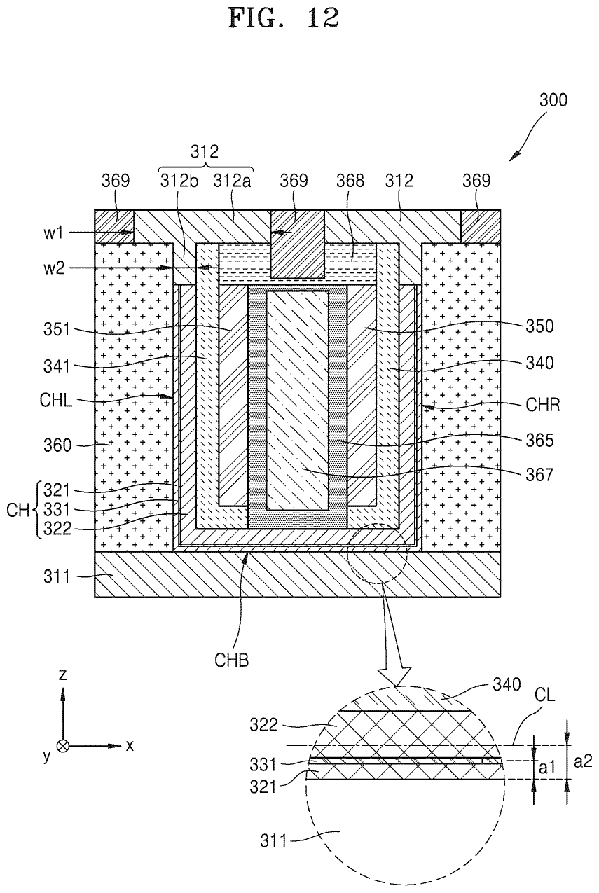

FIG. 12 illustrates a semiconductor device 300 according to some example embodiments.

The semiconductor device 300 may include a first electrode 311, the channel CH provided in the first electrode 311, and a second electrode 312 provided in the channel CH.

The channel CH may have a U-shaped cross-section, such as a sharp-U shaped cross-section. The channel CH may include a plurality of oxide semiconductor layers 321 and 322, and a crystallization prevention layer 331 disposed between the plurality of oxide semiconductor layers 321 and 322. The plurality of oxide semiconductor layers 321 and 322 and the crystallization prevention layer 333 may each have a U-shaped cross-section. The channel CH may include a bottom portion CHB in contact with the first electrode 311, a first vertical extension portion CHR extending in a direction (Z direction) perpendicular to the first electrode 311 from one end of the bottom portion CHB, and a second vertical extension portion CHL extending in the direction (Z direction) perpendicular to the first electrode 311 from the other end of the bottom portion CHB.

A first gate electrode 350 may be spaced apart from the first vertical extension portion CHR, and a second gate electrode 351 may be spaced apart from the second vertical extension portion CHL. A first gate insulating layer 340 may be provided between the first vertical extension portion CHR and the first gate electrode 350, and a second gate insulating layer 341 may be provided between the second vertical extension portion CHL and the second gate electrode 351.

The first gate electrode 350 and/or the second gate electrode 351 may extend in a second horizontal direction y. The first gate electrode 350 and the second gate electrode 351 may be spaced apart from each other. The first gate electrode 350 and/or the second gate electrode 351 may constitute a word line (e.g., a row line). An electrical signal input to the first gate electrode 350 may not match an electrical signal input to the second gate electrode 351. The first gate electrode 350 may control a channel of the first vertical extension portion CHR, and the second gate electrode 351 may control a channel of the second vertical extension portion CHL.

An insulating liner 365 may be disposed between the first gate electrode 350 and the second gate electrode 351, which are spaced apart from each other. The insulating liner 365 may be conformally disposed on sidewalls of the first gate electrode 350 and the second gate electrode 351 facing each other, and/or an upper surface of the channel CH. The insulating liner 365 may have an upper surface disposed on the same plane as the first gate electrode 350 and the second gate electrode 351. The insulating liner 365 may include, for example, silicon nitride. A buried insulating layer 367 may fill a space between the first gate electrode 350 and the second gate electrode 351 spaced apart from each other on the insulating liner 365. The buried insulating layer 367 may include, for example, silicon oxide. An upper insulating layer 368 may be disposed on an upper surface of the first gate electrode 350, the second gate electrode 351, and/or the buried insulating layer 367. An upper surface of the upper insulating layer 368 may be disposed at the same level as an upper surface of a mold insulating layer 360.

The second electrode 312 may be disposed on an upper portion of the channel CH. The second electrode 312 may serve as a landing pad. The second electrode 312 may include an upper left electrode and an upper right electrode. The upper right electrode may be electrically connected to the first vertical extension portion CHR. The upper left electrode may be electrically connected to the second vertical extension portion CHL. The upper left electrode and the upper right electrode may not be electrically connected to each other. The second electrode 312 may include an upper portion 312a and a lower portion 312b, which have different widths. The upper portion 312a of the second electrode 312 may be disposed at a higher level than that of an upper surface of the mold insulating layer 360. The lower portion 312b of the second electrode 312 may be disposed inside a recess defined between the mold insulating layer 360 and the upper insulating layer 368. In some example embodiments, the upper portion 312a of the second electrode 312 may have a first width w1 in a first horizontal direction x, and the lower portion 312b of the second electrode 312 may have a second width w2 greater than the first width w1 in the first horizontal direction x. The lower portion 312b of the second electrode 312 may have a bottom surface disposed inside the recess, and the upper portion 312a of the second electrode 312 on the upper surface of the mold insulating layer 360 and the upper surface of the upper insulating layer 368 on the lower portion 312b of the second electrode 312, and accordingly, the second electrode 312 may have a T-shaped vertical cross-section. The bottom surface of the lower portion 312b of the second electrode 312 may in contact with surface upper portions of the first vertical extension portion CHR and/or the second vertical extension portion CHL. First and second sidewalls of the lower portion 312b of the second electrode 312 may be aligned with first and second sidewalls of the first vertical extension portion CHR and the second vertical extension portion CHL. The bottom surface of the lower portion 312b of the second electrode 312 may be disposed at a level equal to or higher than an upper surface of the first gate electrode 350 and/or the second gate electrode 351, and a part of the sidewall of the lower portion 312b of the second electrode 312 may be covered by the first gate insulating layer 350 and/or the second gate electrode 351. An insulating layer 369 surrounding the second electrode 312 may be disposed on the upper surfaces of the mold insulating layer 360 and the upper insulating layer 368. The semiconductor device 300 may have a vertical channel transistor (VCT) structure including the vertical channel CH extending in the direction z perpendicular to the first electrode 311. The second gate insulating layer 341 may have an L-shaped cross-section, and the first gate insulating layer 340 may have a cross-section symmetrical to the second gate insulating layer 341 with respect to the buried insulating layer 367. The first gate electrode 350 and the second gate electrode 351 may have a straight cross-section. Alternatively, the first gate insulating layer 340 and the second gate insulating layer 341 may have a straight cross-section, like the first gate electrode 350 and the second gate electrode 351.

Meanwhile, the channel CH is described in more detail. The first electrode 311 may be a source electrode, and the second electrode 312 may be a drain electrode, or the first electrode 311 may be a drain electrode, and the second electrode 312 may be a source electrode. The crystallization prevention layer 331 on the bottom portion CHB of the channel CH may be disposed relatively closer to the first electrode 311. A distance a1 from a lower interface of the channel bottom portion CHB to the crystallization prevention layer 331 may be less than a distance a2 from the lower interface of the channel bottom portion CHB to the center line CL. Here, the center line CL may be a position of ½ thickness of the channel CH. The distance a1 from a lower interface of the channel bottom portion CHB to the crystallization prevention layer 331 is defined as a position of ½ thickness of the crystallization prevention layer 331 from the lower interface of the channel bottom portion CHB. As described above, when the crystallization prevention layer 331 is disposed relatively close to the first electrode 311, the crystallization suppression effect by the crystallization prevention layer 331 may be enhanced. This is because crystallization of the channel CH occurs first from the side close to the source electrode or the drain electrode.

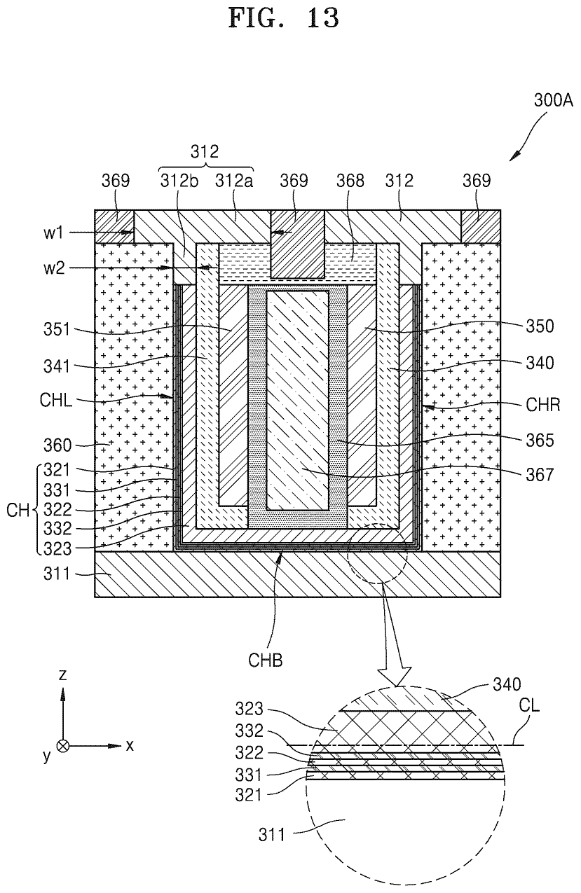

FIG. 13 illustrates a semiconductor device 300A including a plurality of first and second crystallization prevention layers 331 and 332. In the semiconductor device 300A, the channel CH may have a structure in which a first oxide semiconductor layer 321, the first crystallization prevention layer 331, a second oxide semiconductor layer 322, the second crystallization prevention layer 332, and a third oxide semiconductor layer 323 are sequentially stacked. The first crystallization prevention layer 331 and the second crystallization prevention layer 332 may be disposed between an interface between the channel CH and the first electrode 311 and the center line CL of the channel CH.

As shown in FIG. 13, when the first and second plurality of crystallization prevention layers 331 and 332 are provided, the plurality of crystallization first and second prevention layers 331 and 332 may all be disposed relatively close to the first electrode 311. However, the disclosure is not limited thereto.

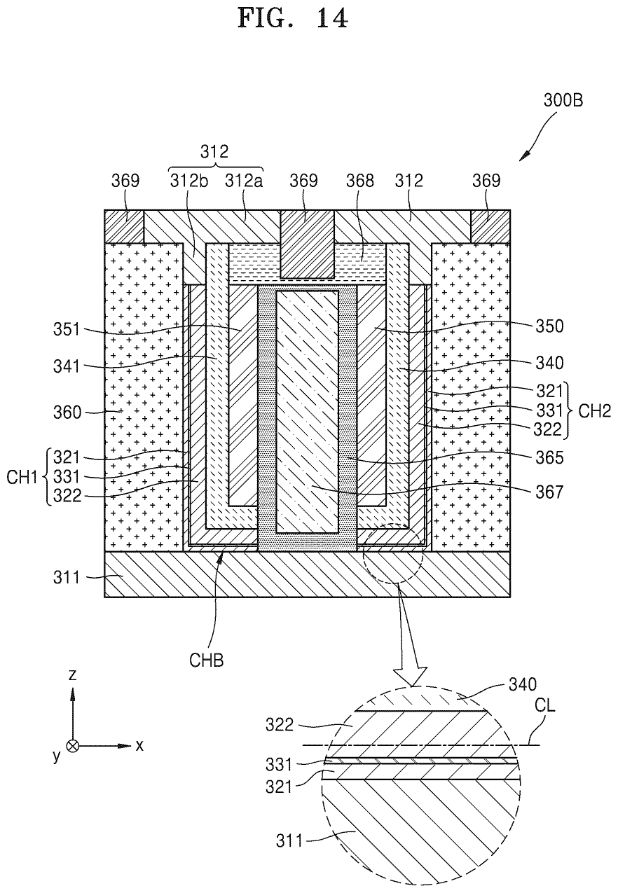

FIG. 14 illustrates a semiconductor device 300B according to some example embodiments.

In FIG. 14, components using the same reference numerals as in FIG. 12 have substantially the same configurations and effects, and thus detailed descriptions thereof are omitted.

In FIG. 14, compared with FIG. 12, a shapes of the channel CH may be different. The channel CH may include a first channel CH1 and a second channel CH2. The first channel CH1 may have an L-shaped cross-section, and the second channel CH2 may have a symmetrical shape with respect to the first channel CH1 in the Z direction. The first channel CH1 and the second channel CH2 are separated from each other.

The first channel CH1 and the second channel CH2 may be located with their longitudinal directions in the direction (Z direction) perpendicular to a substrate (not shown). In the channel bottom portion CHB of the first channel CH1, the first crystallization prevention layer 331 may be disposed between an interface between the first channel CH1 and the first electrode 311 and the center line CL of the first channel CH1. In the channel bottom portion CHB of the second channel CH2, the first crystallization prevention layer 331 may be disposed between an interface between the second channel CH2 and the first electrode 311 and the center line CL of the second channel CH2.

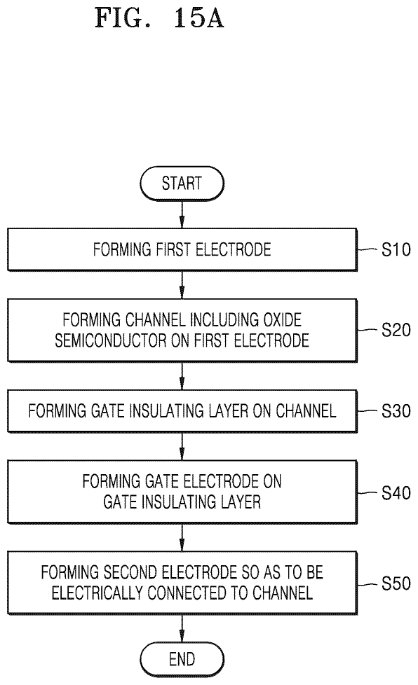

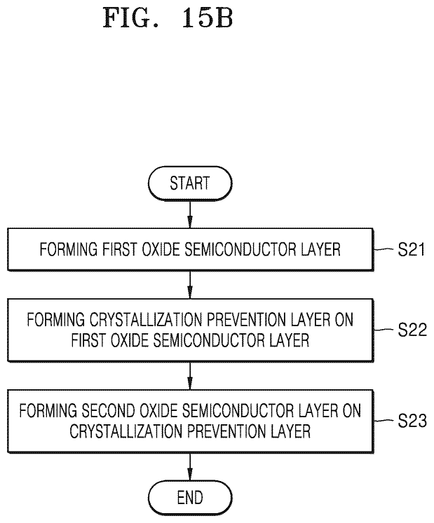

FIGS. 15A and 15B are flowcharts illustrating a method of manufacturing a semiconductor device according to some example embodiments.

Referring to FIG. 15A, the method of manufacturing the semiconductor device according to some example embodiments includes forming a first electrode (S10) and forming a channel including an oxide semiconductor on the first electrode (S20). The channel may be deposited using, for example, an ALD process and/or a PE-ALD process. A gate insulating layer may be formed on the channel (S30). A gate electrode is formed on the gate insulating layer (S40). A second electrode is formed so as to be electrically connected to the channel (S50).

FIG. 15B shows a process of forming the channel. An operation of forming the channel may include forming a first oxide semiconductor layer (S21), forming a crystallization prevention layer on the first oxide semiconductor layer (S22), and forming a second oxide semiconductor layer on the crystallization prevention layer (S23). The first oxide semiconductor layer, the crystallization prevention layer, and the second oxide semiconductor layer may be deposited by using an ALD process, e.g., by using an in-situ ALD process that is performed in one process step and/or one process operation; example embodiments are not limited thereto. Operations S22 and S23 may be repeated n times. Operations S22 and S23 may be repeated n times. Here, n may be 10 times or less. For example, n may be 5 times or less. For example, n may be 3 times or less. The oxide semiconductor layer, the crystallization prevention layer, and the oxide semiconductor layer configure the minimum channel, and the number of oxide semiconductor layers and crystallization prevention layers may be adjusted within a range in which a ratio of the sum of the thickness of the crystallization prevention layer to the total thickness of the channel is in a range of about 0.01 to about 0.6.

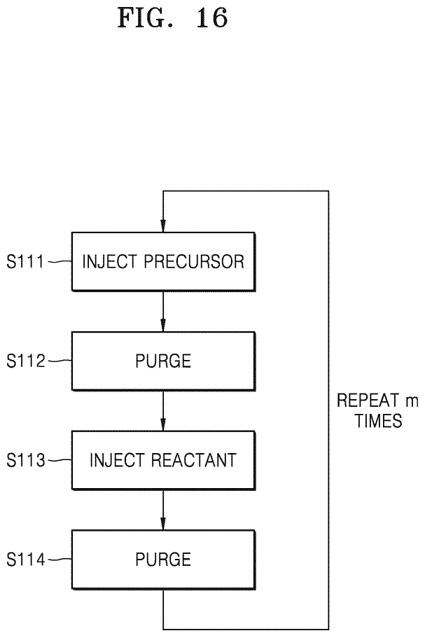

FIG. 16 is a flowchart illustrating a process of depositing an oxide semiconductor layer and a crystallization prevention layer. Referring to FIG. 16, operations S20 and S40 of depositing the oxide semiconductor layer and operation S30 of depositing the crystallization prevention layer may include an ALD process.

The ALD process may include operation S111 of injecting a precursor into a chamber, purge operation S112, operation S113 of injecting a reactant into the chamber to react with the precursor, and purge operation S114. Operations S111, S112, S113, and S114 may be repeated m times (m is a natural number), for example, 1 to 100 times. For example, m may include a range of 1 to 70 times. In some cases operations may be performed for the same amount of time under the same conditions for each iteration; however, example embodiments are not limited thereto, and in one or more iterations, a process may be different than in other iterations.

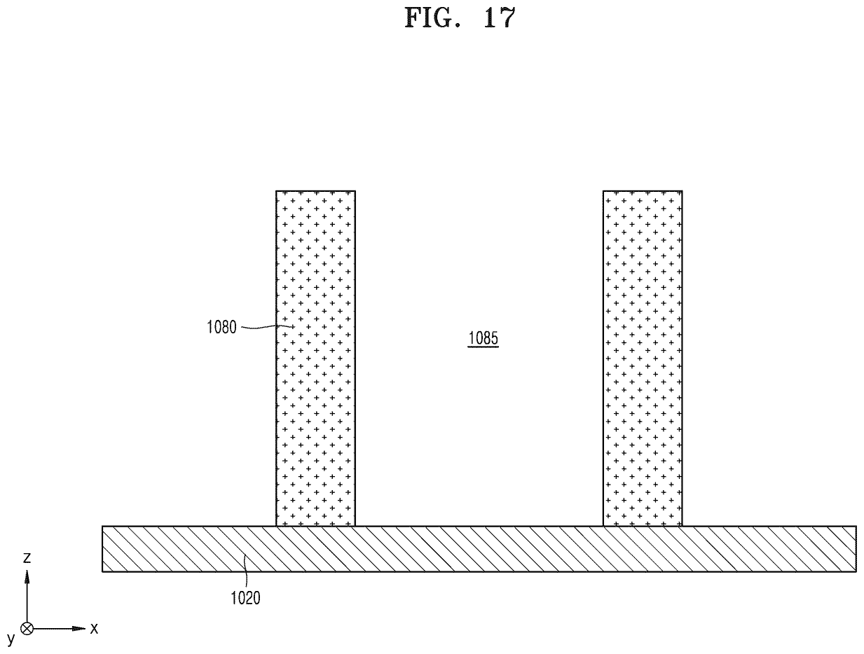

Next, a method of manufacturing a semiconductor device according to some example embodiments is described with reference to FIGS. 17 to 30.

Referring to FIG. 17, a plurality of mold insulating layers 1080 extending in the second horizontal direction y may be deposited on a lower electrode 1020 extending in the first horizontal direction x. The mold insulating layer 1080 may be stacked to a certain height in the vertical direction z. The plurality of mold insulating layers 1080 and the lower electrode 1020 may form an opening 1085.

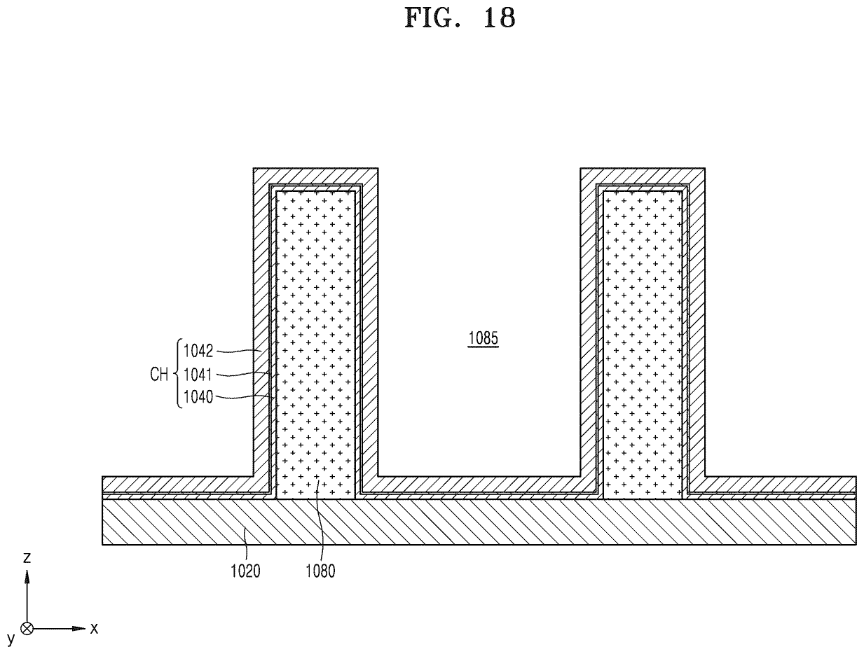

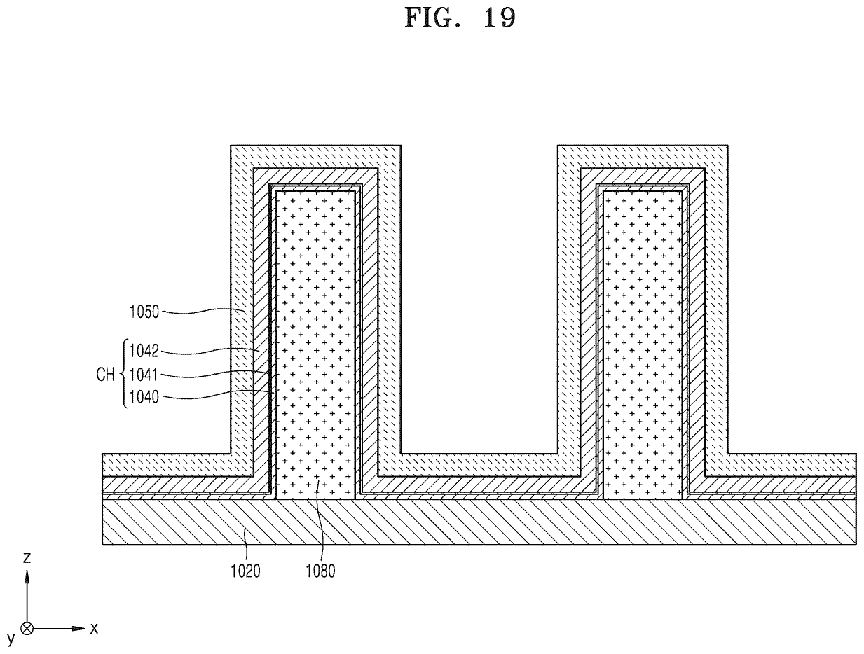

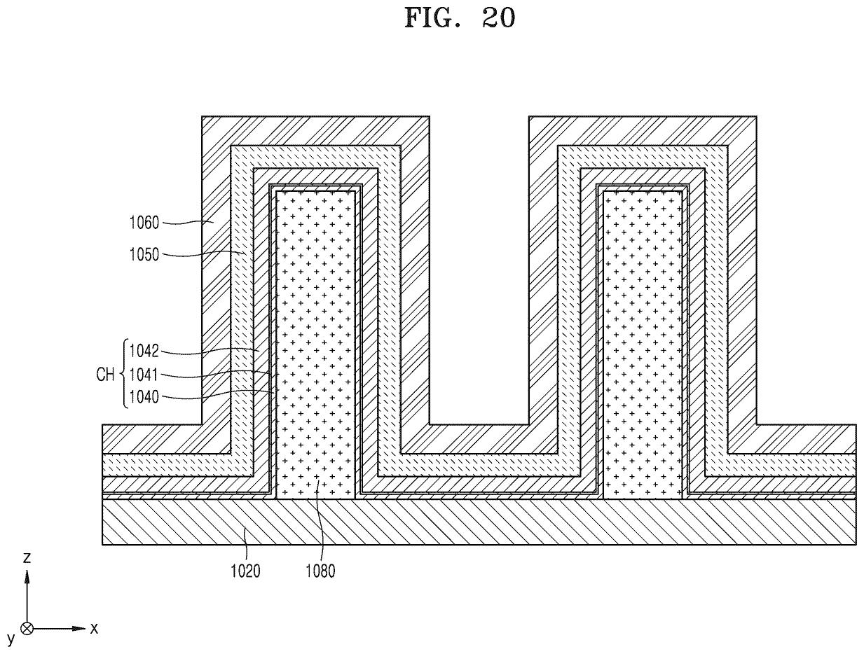

Referring to FIG. 18, a first oxide semiconductor layer 1040, a crystallization prevention layer 1041, and a second oxide semiconductor layer 1042 may be deposited on the lower electrode 1020 and the mold insulating layer 1080. The first oxide semiconductor layer 1040, the crystallization prevention layer 1041, and the second oxide semiconductor layer 1042 may constitute the channel CH. The first oxide semiconductor layer 1040, the crystallization prevention layer 1041, and the second oxide semiconductor layer 1042 may be deposited in an ALD method, e.g., in an in-situ ALD method. The channel CH may have a U-shaped cross-section. Referring to FIG. 19, a gate insulating layer 1050 may be deposited in the second oxide semiconductor layer 1042. Referring to FIG. 20, a gate electrode 1060 may be deposited on a gate insulating layer 1060.

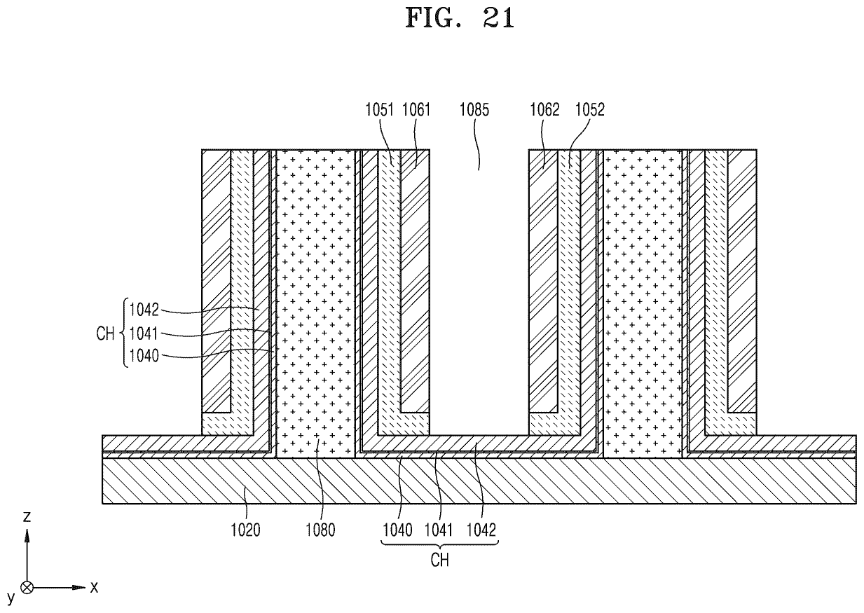

Referring to FIG. 21, anisotropic etching, e.g., a dry etching, is performed on the gate electrode 1060 of a structure shown in FIG. 20, so that the second oxide semiconductor layer 1042 may be exposed. Accordingly, the gate electrode 1060 may be separated into a first gate electrode 1061 and a second gate electrode 1062, and the gate insulating layer 1050 may be separated into a first gate insulating layer 1051 and a second gate insulating layer 1052. In addition, the gate electrode 1060, the gate insulating layer 1050, and the channel CH may be etched in a direction of an upper portion of the mold insulating layer 1080 so that an upper surface of the mold insulating layer 1080 may be exposed. An upper surface level of the mold insulating layer 1080, an upper surface level of the channel CH, upper surface levels of the first gate electrode 1061 and the second gate electrode 1062, and upper surface levels of the first gate insulating layer 1051 and the second gate insulating layer 1052 may coincide with each other.

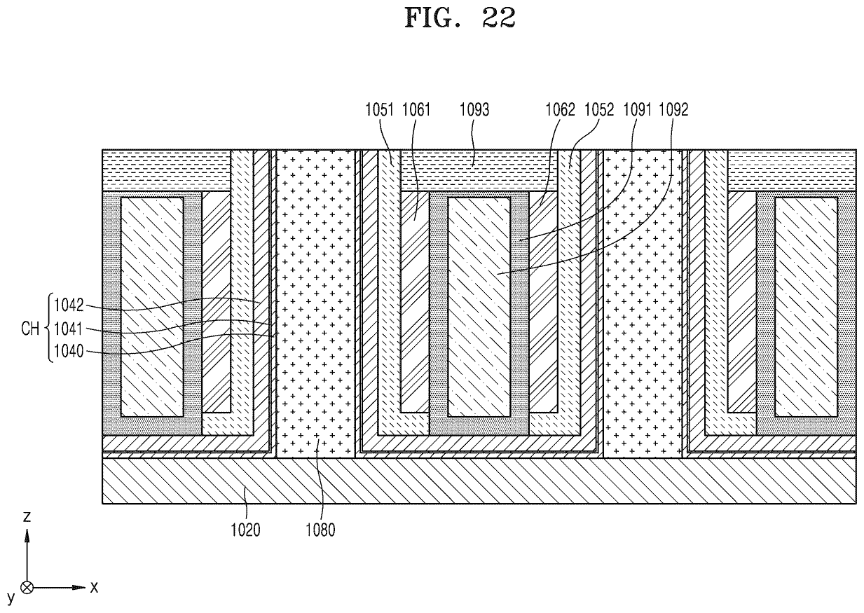

Referring to FIG. 22, when etching is performed on the gate electrode 1060 once more, the upper surface levels of the first gate electrode 1061 and/or the second gate electrode 1062 may be lower than upper surface level of the mold insulating layer 1080.

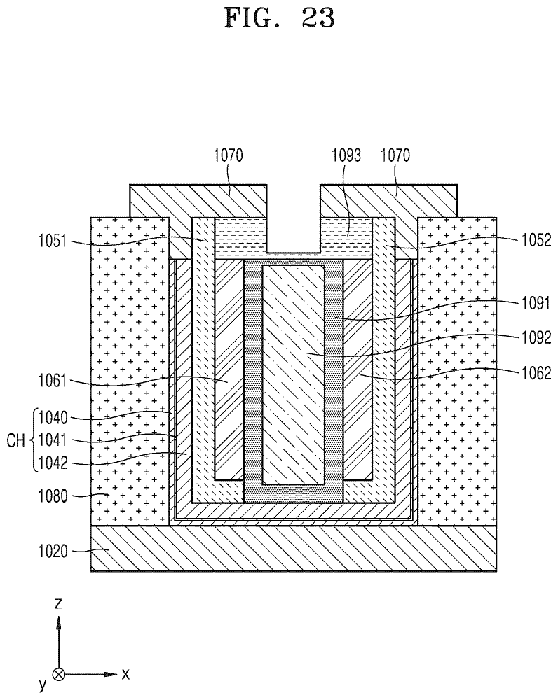

Referring to FIG. 23, an insulating liner 1091 may be deposited from a surface of a bottom portion of the second oxide semiconductor layer 1042 to the upper surface levels of the first gate electrode 1061 and/or the second gate electrode 1062. A buried insulating layer 1092 may be filled inside the insulating liner 1091. The insulating liner 1091 and the buried insulating layer 1092 may not be distinguished from each other. An upper insulating layer 1093 may be deposited on upper surfaces of the first gate electrode 1061 and/or the second gate electrode 1062 and an upper surface of the insulating liner 1091. A surface level of the upper insulating layer 1093 may coincide with the upper surface level of the mold insulating layer 1080, the upper surface level of the channel CH, and the upper surface levels of the first gate insulating layer 1051 and the second gate insulating layer 1052.

FIG. 23 illustrates only a portion corresponding to one pixel in FIG. 22 for convenience. Referring to FIG. 23, a part of an upper portion of the channel CH may be etched, and an upper electrode 1070 may be deposited on the upper portion of the channel CH. After the upper electrode 1070 is deposited, and a central portion of the upper electrode 1070 and an upper portion of the upper insulating layer 1093 may be partially etched.

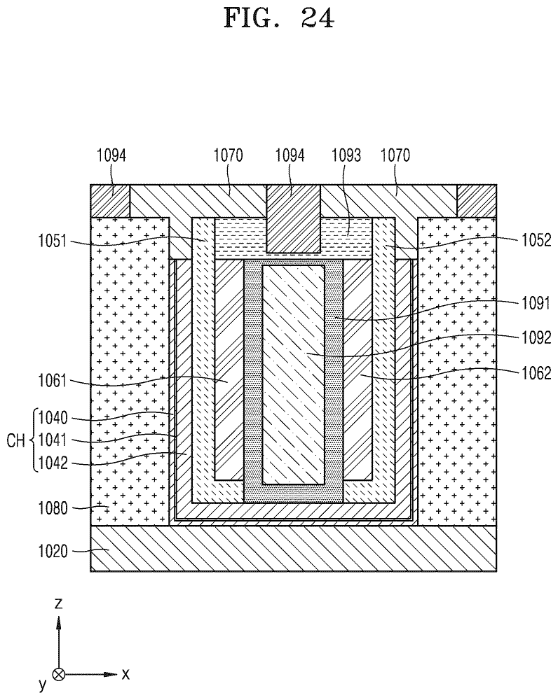

Referring to FIG. 24, an insulating layer 1094 may be deposited between the upper electrode 1070 and the upper electrode 1070 and a part of the upper portion of the upper insulating layer 1093. An upper surface level of the insulating layer 1094 and a surface level of the upper electrode 1070 may coincide with each other.

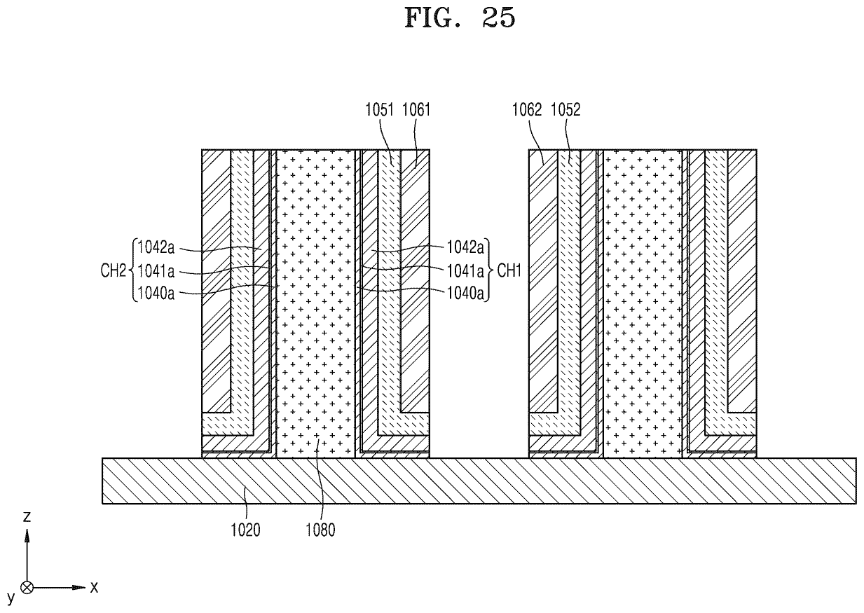

FIG. 25 is a diagram illustrating a method of manufacturing a semiconductor device illustrated in FIG. 14. Hereinafter, descriptions redundant with those of FIG. 21 are omitted and differences are mainly described.

Referring to FIG. 25, the gate electrode 1060, the gate insulating layer 1050, and the channel CH may be etched in a direction of a bottom portion of an opening 1085 so that a surface of the lower electrode 1020 may be partially exposed. Thus, the channel CH may be separated into a first channel CH1 and a second channel CH2. Each of the first channel CH1 and the second channel CH2 may include a first oxide semiconductor layer 1040a, a crystallization prevention layer 1041a, and a second oxide semiconductor layer 1042a.

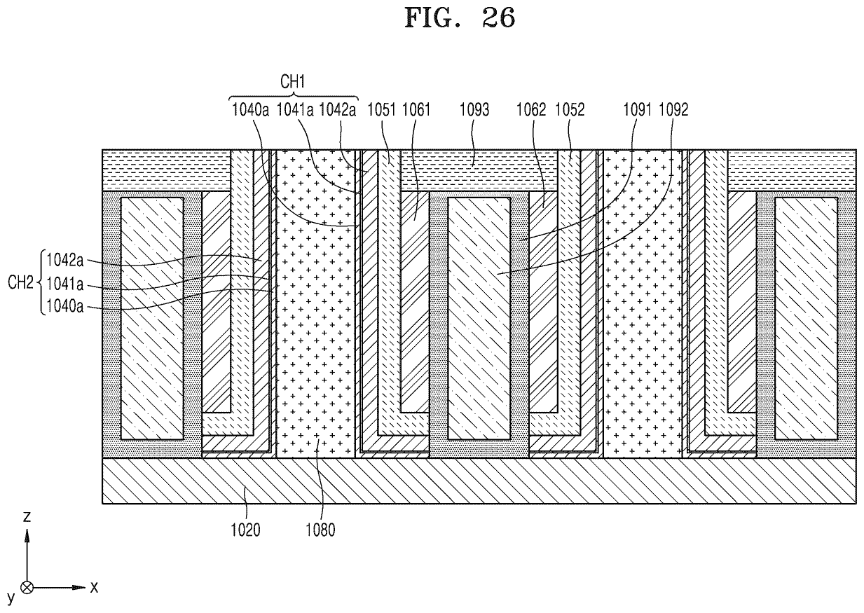

Referring to FIG. 26, the insulating liner 1091 may be deposited from an upper surface of the lower electrode 1020 to upper surface levels of the first gate electrode 1061 and/or the second gate electrode 1062.

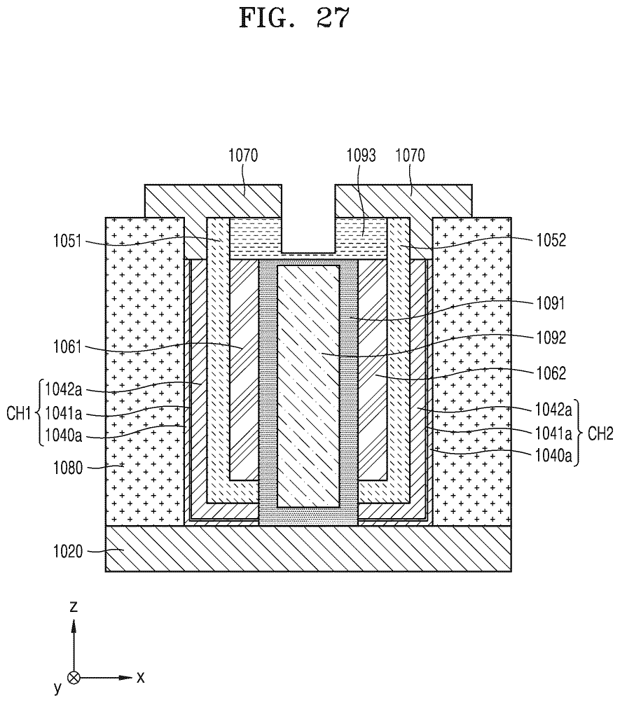

Referring to FIG. 27, similar to FIG. 24, upper portions of the first channel CH1 and the second channel CH2 may be partially etched, and the upper electrode 1070 may be deposited on the upper portions of the first channel CH1 and the second channel CH2. After the upper electrode 1070 is deposited, and a central portion of the upper electrode 1070 and an upper portion of the upper insulating layer 1093 may be partially etched.

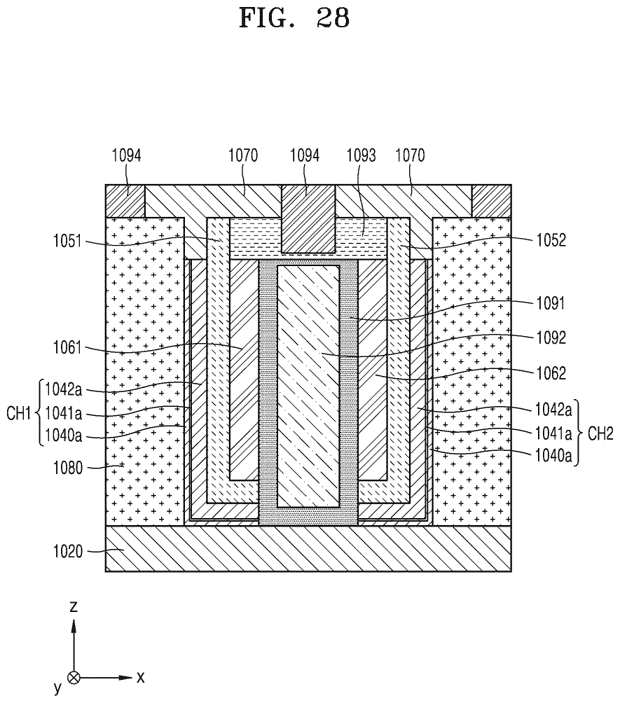

Referring to FIG. 28, similar to FIG. 25, the insulating layer 1094 may be deposited between the upper electrode 1070 and the upper electrode 1070 and a part of the upper portion of the upper insulating layer 1093. An upper surface level of the insulating layer 1094 and a surface level of the upper electrode 1070 may coincide with each other.

As described above, the semiconductor device according to some example embodiments may form a channel including an oxide semiconductor layer and a crystallization prevention layer by using an ALD process.

The semiconductor device according to some example embodiments may be applied to, for example, a transistor, a field effect transistor (FET), a semiconductor memory device, a logic device, an image sensor, etc. The logic device is in charge of computation and control, and the memory device is in charge of storing information. The logic device may be applied to a micro component, an analog IC, a logical IC, etc. The analog IC may include a power semiconductor, an image sensor, a touch controller, etc. The logical IC may include a display driver IC (DDI), a T-CON, a media IC, an application processor (AP), a vehicle semiconductor, etc. The memory device may include a DRAM, an SRAM, a NAND memory, etc.

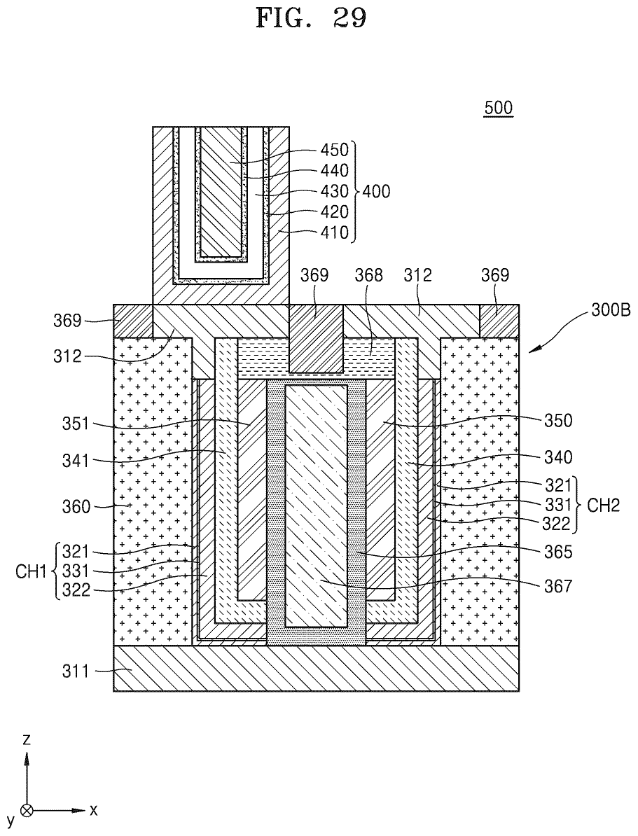

FIG. 29 illustrates an example in which the semiconductor device 300B is applied to a DRAM according to some example embodiments. The semiconductor device 300B is the same as that described with reference to FIG. 15, and thus, a detailed description thereof is omitted for simplicity of description.

Referring to FIG. 29, a memory device 500 may include the semiconductor device 300B and a capacitor 400 connected to an upper electrode 370 of the semiconductor device 300.

The capacitor 400 may include a first electrode 410, a dielectric layer 430, and a second electrode 450. The dielectric layer 430 may include at least one of, for example, HfO₂, ZrO₂, CeO₂, La₂O₃, Ta₂O₃, or TiO₂. A lower interfacial layer 420 may be further provided between the first electrode 410 and the dielectric layer 430. The lower interfacial layer 420 may include a material expressed in MM′ON, M′O, or M′ON, M may include any one or more of Be, B, Na, Mg, Al, Si, K, Ca, Sc, Ti, V, Cr, Mn, Fe, Co, Ni, Cu, Zn, Ga, Ge, Rb, Sr, Y, Zr, Nb, Mo, Tc, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, TI, Pb, Bi, Po, Fr, Ra, Ac, Th, Pa, and U, and M′ may include any one of H, Li, Be, B, N, O, Na, Mg, Al, Si, P, S, K, Ca, Sc, Ti, V, Cr, Mn, Fe, Co, Ni, Cu, Zn, Ga, Ge, As, Se, Rb, Sr, Y, Zr, Nb, Mo, To, Ru, Rh, Pd, Ag, Cd, In, Sn, Sb, Te, Cs, Ba, La, Ce, Pr, Nd, Pm, Sm, Eu, Gd, Tb, Dy, Ho, Er, Tm, Yb, Lu, Hf, Ta, W, Re, Os, Ir, Pt, Au, Hg, TI, Pb, Bi, Po, Fr, Ra, Ac, Th, Pa, and U. A leakage current reduction layer 440 may be further provided between the dielectric layer 430 and the upper electrode 450. The leakage current reduction layer 440 may include, for example, an AlZrO layer. However, the leakage current reduction layer 440 is not limited thereto.

As described above, when the semiconductor device 300B according to some example embodiments is applied to the memory device 500, even though the memory device 500 is miniaturized or reduced in size, and is heated at a high temperature in the manufacturing process, the semiconductor device 300B includes the at least one crystallization prevention layer 331 in the channel CH, thereby suppressing or reducing the crystallization of the channel CH.

When a channel including an oxide semiconductor layer is crystallized, there is a problem that a leakage current increases and a threshold voltage distribution degrades due to the formation of a grain boundary. The DRAM subsequent process is performed at the maximum of 550° C. or more, and even in such a high temperature process, the semiconductor device 300B according to some example embodiments maintains an amorphous state, thereby reducing the leakage current and increasing the thermal stability.

In FIG. 29, the semiconductor devices 10, 10A, 10B, 100, 200, 200A, 300, and 300A according to the embodiments described with reference to FIGS. 1 to 14 may be applied instead of the semiconductor device 300B.

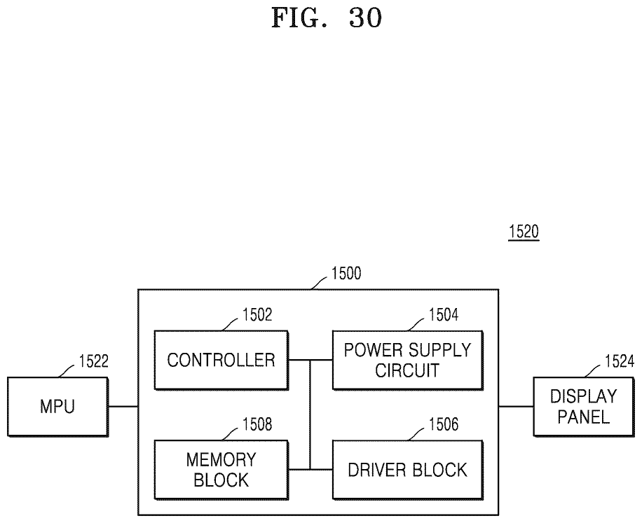

FIG. 30 is a schematic block diagram of a display driver IC (DDI) 1500 and a display device 1520 including the DDI 1500 according to some example embodiments.

Referring to FIG. 30, the DDI 1500 may include a controller 1502, a power supply circuit 1504, a driver block 1506, and a memory block 1508. The controller 1502 receives and decodes a command applied from a main processing unit (MPU) 1522, and controls each of blocks of the DDI 1500 to implement an operation according to the command. The power supply circuit 1504 generates a driving voltage in response to the control of the controller 1502. The driver block 1506 drives a display panel 1524 by using the driving voltage generated by the power supply circuit 1504 in response to the control of the controller 1502. The display panel 1524 may be or may include an LCD panel and/or a micro LED device. The memory block 1508 is a block that temporarily stores a command input to the controller 1502 or control signals output from the controller 1502, or stores necessary data, and may include a memory such as RAM and/or ROM. The power supply circuit 1504 and the driver block 1506 may include the semiconductor devices 10, 10A, 10B, 100, 200, 200A, 300, 300A, and 300B according to some example embodiments described with reference to FIGS. 1 to 14.

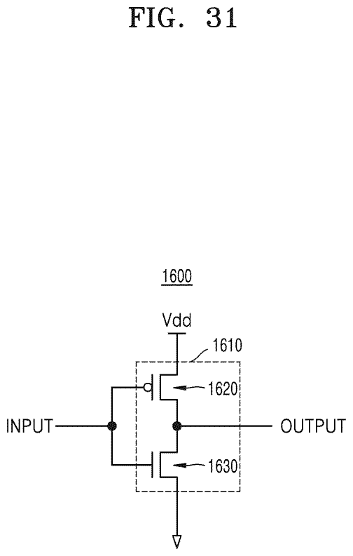

FIG. 31 is a circuit diagram of a CMOS inverter 1600 according to some example embodiments.

The CMOS inverter 1600 includes a CMOS transistor 1610. The CMOS transistor 1610 includes a PMOS transistor 1620 and an NMOS transistor 1630 connected to each other between a power terminal Vdd and a ground terminal. The CMOS transistor 1610 may include any of the semiconductor 10, 10A, 10B, 100, 200, 200A, 300, 300A, and 300B according to some example embodiments described with reference to FIGS. 1 to 14.

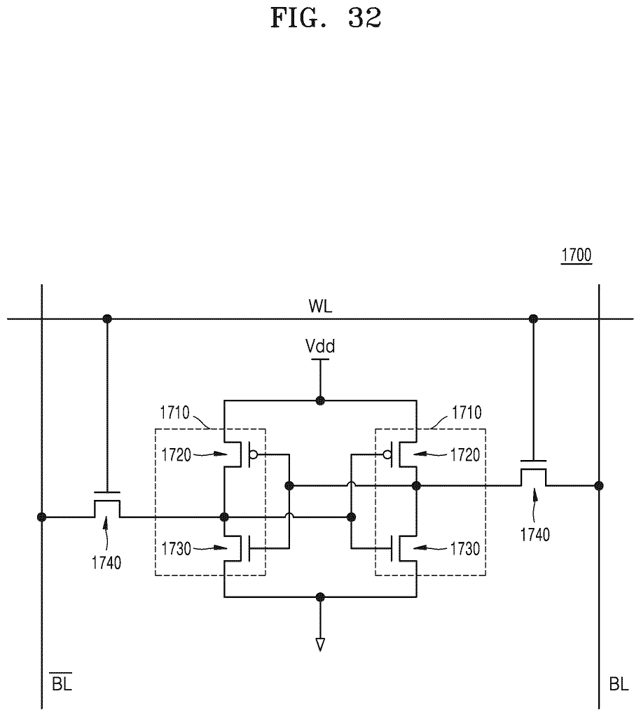

FIG. 32 is a circuit diagram of a CMOS SRAM device 1700 according to some example embodiments.

The CMOS SRAM device 1700 includes a pair of driving transistors 1710. The pair of driving transistors 1710 each include a PMOS transistor 1720 and an NMOS transistor 1730 connected to each other between the power terminal Vdd and a ground terminal. The CMOS SRAM device 1700 may further include a pair of transfer transistors 1740. Sources of the transfer transistors 1740 are cross-connected to a common node of the PMOS transistor 1720 and the NMOS transistor 1730 constituting the driving transistors 1710. The power terminal Vdd is connected to a source of the PMOS transistor 1720, and the ground terminal is connected to a source of the NMOS transistor 1730. A word line WL may be connected to gates of the pair of transmission transistors 1740, and a bit line BL and an inverted bit line may be respectively connected to drains of the pair of transmission transistors 740.

At least one of the driving transistor 1710 or the transmission transistor 1740 of the CMOS SRAM device 1700 may include the semiconductor devices 10, 10A, 10B, 100, 200, 200A, 300, 300A, and 300B according to the embodiments described with reference to FIGS. 1 to 14.

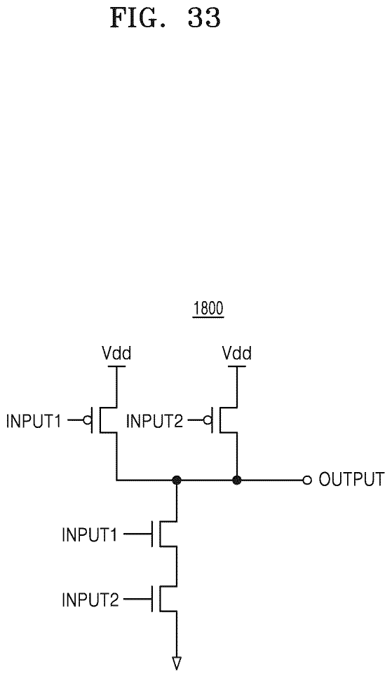

FIG. 33 is a circuit diagram of a CMOS NAND circuit 1800 according to some example embodiments.

The CMOS NAND circuit 1800 includes a pair of CMOS transistors to which different input signals are transmitted. The CMOS NAND circuit 1800 may include the semiconductor devices 10, 10A, 10B, 100, 200, 200A, 300, 300A, and 300B according to the embodiments described with reference to FIGS. 1 to 14.

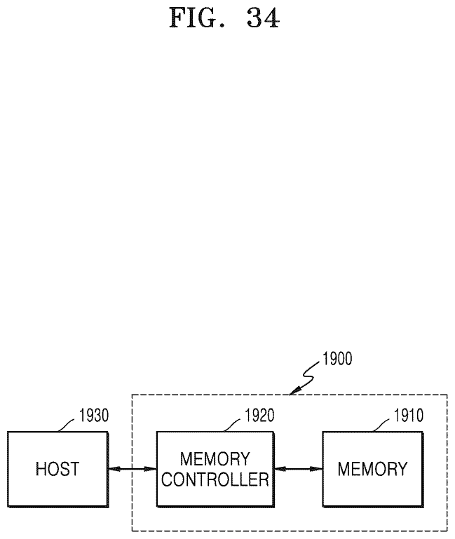

FIG. 34 is a block diagram illustrating an electronic system 1900 according to some example embodiments.

The electronic system 1900 includes a memory 1910 and a memory controller 1920. The memory controller 1920 may control the memory 1910 to read data from the memory 1910 and/or write data to the memory 1910 in response to a request from a host 1930. At least one of the memory 1910 or the memory controller 1920 may include the semiconductor devices 10, 10A, 10B, 100, 200, 200A, 300, 300A, and 300B according to the embodiments described with reference to FIGS. 1 to 14.

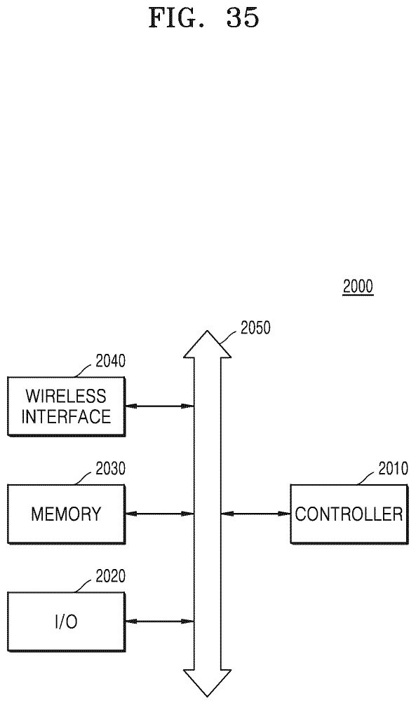

FIG. 35 is a block diagram of an electronic apparatus 2000 according to some example embodiments.

The electronic apparatus 2000 may configure a wireless communication device, or a device capable of transmitting and/or receiving information under a wireless environment. The electronic apparatus 2000 includes a controller 2010, an input/output device (I/O) 2020, a memory 2030, and a wireless interface 2040, which are interconnected through a bus 2050.

The controller 2010 may include at least one of a microprocessor, a digital signal processor, or a processing device similar thereto. The I/O device 2020 may include at least one of a keypad, a keyboard, and a display. The memory 2030 may be used to store a command executed by the controller 2010. For example, the memory 2030 may be used to store user data. The electronic apparatus 2000 may use the wireless interface 2040 to transmit/receive data through a wireless communication network. The wireless interface 2040 may include an antenna and/or a wireless transceiver. The electronic system 2000 may include the semiconductor devices 10, 10A, 10B, 100, 200, 200A, 300, 300A, and 300B according to the embodiments described with reference to FIGS. 1 to 14.

A semiconductor device according to some example embodiments may exhibit good electrical performance with an ultra-small structure, may be therefore applied to an IC device, and may implement miniaturization, low power, and/or high performance.

The semiconductor device according to some example embodiments may include a crystallization prevention layer that suppresses crystallization of an oxide semiconductor layer, thereby reducing a leakage current of the thin semiconductor device. Accordingly, a channel including the oxide semiconductor layer may be formed, and even though the semiconductor device is miniaturized or reduced, thereby achieving a high carrier mobility and/or a high on-off current ratio.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure.

Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a first electrode;
a second electrode spaced apart from the first electrode;
a channel between the first electrode and the second electrode;
a gate insulating layer in the channel; and
a gate electrode provided on the gate insulating layer,
wherein the channel comprises a plurality of oxide semiconductor layers spaced apart from each other and a crystallization reduction layer between the plurality of oxide semiconductor layers,
a total thickness of the channel is in a range of 5 nm to 10 nm,
the channel is in an amorphous state, and
the crystallization reduction layer has a thickness in a range of 1 Å to 10 Å.

2. The semiconductor device of claim 1, wherein the semiconductor device has a vertical channel structure in which the first electrode is below the channel and the second electrode is above the channel.

3. The semiconductor device of claim 1, wherein a ratio of a sum of the thickness of the crystallization reduction layer to the total thickness of the channel is in a range of 0.01 to 0.6.

4. The semiconductor device of claim 1, wherein the channel is configured not have a peak value at a crystallization angle in a range of 29° to 34°.

5. The semiconductor device of claim 1, wherein the plurality of oxide semiconductors layer are an oxide including at least one of indium, gallium, or zinc.

6. The semiconductor device of claim 5, wherein the crystallization reduction layer includes at least one of aluminum oxide, gallium oxide, silicon oxide, zirconium oxide, hafnium oxide, silicon nitride, aluminum nitride, and gallium nitride.

7. The semiconductor device of claim 1, wherein the crystallization reduction layer does not include any same element as the plurality of oxide semiconductor layers.

8. The semiconductor device of claim 1, wherein
a part of the channel faces the first electrode or the second electrode, and the crystallization reduction layer of the channel is between an interface between the channel and the first electrode and a center line of the channel or between an interface between the channel and the second electrode and the center line of the channel.

9. The semiconductor device of claim 1, wherein the crystallization reduction layer includes a material having an energy bandgap greater than an energy band gap of each of the plurality of oxide semiconductor layers.

10. The semiconductor device of claim 1, wherein an upper surface and a lower surface of the crystallization reduction layer are each in direct contact with the plurality of oxide semiconductor layers.

11. The semiconductor device of claim 1, wherein the gate electrode surrounds the channel.

12. The semiconductor device of claim 1, wherein the channel, the gate insulating layer, and the gate electrode are arranged with their longitudinal directions in a vertical direction of the semiconductor device and are arranged in a horizontal direction of the semiconductor device.

13. The semiconductor device of claim 1, wherein the channel includes a bottom portion in contact with the first electrode, a first vertical extension portion extending in a direction perpendicular to the first electrode from one end of the bottom portion, and a second vertical extension portion extending in the direction perpendicular to the first electrode from the other end of the bottom portion.

14. The semiconductor device of claim 1, wherein the channel has a crystallization temperature of 700° C. or more.

15. An electronic apparatus comprising:
a memory comprising at least one semiconductor device; and
a memory controller,
wherein the at least one semiconductor device comprises:
a first electrode;
a second electrode spaced apart from the first electrode;
a channel between the first electrode and the second electrode;
a gate insulating layer in the channel; and
a gate electrode on the gate insulating layer,
the channel comprises a plurality of oxide semiconductor layers spaced apart from each other, and a crystallization reduction layer disposed between the plurality of oxide semiconductor layers,
a total thickness of the channel is in a range of 5 nm to 10 nm,
the channel is in an amorphous state, and
the crystallization reduction layer has a thickness in a range of 1 Å to 10 Å.

16. A method of manufacturing a semiconductor device, the method comprising:
forming a first electrode;
forming a channel comprising an oxide semiconductor on the first electrode;
forming a gate insulating layer on the channel;
forming a gate electrode on the gate insulating layer above; and
forming a second electrode so as to be electrically connected to the channel,
wherein the forming of the channel comprises:
forming a first oxide semiconductor layer;
forming a crystallization reduction layer on the first oxide semiconductor layer; and
forming a second oxide semiconductor layer on the crystallization reduction layer, and
the crystallization reduction layer includes a material having an energy bandgap greater than an energy band gap of each of the first oxide semiconductor layer and the second oxide semiconductor layer.

17. The method of claim 16, wherein the first oxide semiconductor layer, the crystallization reduction layer, and the second oxide semiconductor layer are formed by an atomic layer deposition (ALD) method.

18. The method of claim 16, wherein the channel has a thickness in a range of 5 nm to 10 nm.

19. The method of claim 16, wherein the crystallization reduction layer has a thickness in a range of 1 Å to 10 Å.

20. The method of claim 16, wherein the channel includes one or more crystallization reduction layers, and a ratio of a sum of a total thickness of the crystallization reduction layer to a total thickness of the channel is in a range of 0.01 to 0.6.
